(19) United States
(12) Patent Application Publication
(10) Pub. No.: US 2014/0209154 A1
(43) Pub. Date: Jul. 31, 2014

(54) Embedded Nanopatterns for Optical Absorbance and Photovoltaics

(71) Applicants: Michael J. Naughton, Brighton, MA (US); Michael J. Burns, Bedford, MA (US); Fan Ye, Boston, MA (US)

(72) Inventors: Michael J. Naughton, Brighton, MA (US); Michael J. Burns, Bedford, MA (US); Fan Ye, Boston, MA (US)

(21) Appl. No.: 14/239,597

(22) PCT Filed: Aug. 17, 2012
(86) PCT No.: PCT/US2012/051325

§ 371 Date: Feb. 19, 2014

Related U.S. Application Data
(60) Provisional application No. 61/525,347, filed on Aug. 19, 2011.

(51) Int. Cl. H01L 31/0352; H01L 31/0232

(52) U.S. Cl. CPC H01L 31/035209; H01L 31/02327
USPC 136/252; 438/69

(57) ABSTRACT

Devices and methods for enhancing optical absorbance and photovoltaics are disclosed. In some embodiments, a light absorbing device comprises a light absorbing material having a front surface and a back surface, and a planar array of nanostructures embedded within the light absorbing material between the front surface and the back surface of the light absorbing material. The nanostructures may be formed from a metallic material.

### RELATED APPLICATIONS

This application claims the benefit of and priority to U.S. Provisional Application No. 61/525,347, filed on Aug. 19, 2011, which is incorporated herein by reference in its entirety.

### FIELD

The embodiments disclosed herein relate to light absorbing devices, and more particularly to light absorbing devices with an embedded nanopattern.

### BACKGROUND

Solar cells with thin absorbers are generally more efficient at extracting electrons as current, but such solar cells are less efficient at collecting and absorbing light. Semiconductors (e.g. silicon, germanium, gallium-arsenide) absorb light radiation to varying degrees by the interaction of light with electrons. The energy E carried by light/radiation depends on its electromagnetic frequency ν and Planck's constant h, that is, E=hν. In semiconductors, this energy can be transferred to electrons in the semiconductor valence band, which can cause the electron to occupy the semiconductor conduction band and become a mobile electron that can be extracted as electrical current. The ability of a semiconductor to absorb radiation is characterized by its wavelength-dependent (or frequency-dependent, since wavelength λ. is related to frequency ν via ν=c/λ, where c is the speed of light) absorption coefficient α. Currently, significant efforts are aimed at increasing light absorption in a light absorbing layer of thin-film solar cells, while simultaneously making the light absorbing layer itself thinner to enable more efficient carrier extraction and reduced material consumption.

### SUMMARY

Devices and methods for enhancing optical absorbance and photovoltaics are disclosed herein. According to aspects illustrated herein, there is provided a light absorbing device comprising a light absorbing material having a front surface and a back surface, and a planar array of metallic nanostructures embedded within the light absorbing material between the front surface and the back surface of the light absorbing material.

According to aspects illustrated herein, there is provided a photovoltaic cell comprising a photovoltaic junction having a light absorbing layer; a planar array of metallic nanostructures embedded within the light-absorbing layer; and a front electrode and a rear electrode electrically connected to the photovoltaic junction to collect electrical current generated in the photovoltaic junction.

According to aspects illustrated herein, there is provided a method for forming a light absorbing device comprising: providing a first thickness of a first photovoltaic material; disposing a planar array of metallic nanostructures on a surface of the first photovoltaic material; and adding a second thickness of the first photovoltaic material over the metal layer.

According to aspects illustrated herein, there is provided a method for increasing light absorption in a light absorbing material, the method comprising: providing a light absorbing material having a light absorbing surface and a back surface opposite the light absorbing surface; and embedding a planar nanopattern of nanostructures into the light absorbing material between the light absorbing surface and the back surface, wherein, upon exposure of the light absorbing material, absorption of light by the light absorbing material is increased.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 is a schematic diagram of an embodiment of a light absorbing layer of the present disclosure.

FIG. 2 is a front view of an embodiment of a nanopattern of the present disclosure.

FIGS. 3A-3G present examples of embodiment unit cells of embedded nanopatterns positioned within a light absorbing layer of the present disclosure.

FIG. 4A and FIG. 4B are schematic diagrams of an embodiment of a light absorbing layer of the present disclosure, in which nanostructures are enclosed within an insulating coating.

FIG. 4C shows the enhanced power loss density, corresponding to enhanced electric-field/optical absorbance in the light absorbing material in the vicinity of a nanopattern, including outside an insulating coating around a nanopattern.

FIG. 5A and FIG. 5B are schematic diagrams of a p-i-n photovoltaic junction and a p-n photovoltaic junction, respectively, that include a light absorbing layer of the present disclosure.

FIG. 6A and FIG. 6B are schematic diagrams of photovoltaic cells that include embodiments of a light absorbing layer of the present disclosure.

FIG. 7 illustrates an insulated cross-shaped nanostructure assembled from insulated smaller nanoparticles.

FIG. 8 illustrates an embodiment imprint stamp to be used to transfer or assemble nanostructures in a semiconductor layer according to the methods of the present disclosure.

FIG. 9A illustrates a 400 nm×400 nm unit cell for simulations of an infinite array of metallic squares embedded in an a-Si absorber layer in an alternating square pattern.

FIG. 9B presents a graph of simulated optical absorbance of the structure for various metals, for light incident from the glass side. Similar results are obtained for light incident from the vacuum side. The simulated layer thicknesses were: 50 nm ITO, 60 nm a-Si, 500 nm glass, 20 nm EMN, with the EMN embedded by a distance of 25 nm into the a-Si below the glass surface.

FIG. 10 presents a graph of optical absorption enhancement factor A(a-Si+EMN)/A(a-Si).

FIG. 11A a cross-shaped nanopattern in a-Si, positioned on ITO-glass.

FIG. 11B presents a graph of simulated optical absorbance with and without an embedded cross-shaped metal nanopattern.

FIG. 12 presents results of simulations of optical absorbance for alternating square nanopattern of FIG. 9A dimensions on Ag substrate, as shown in inset, for various depths d as indicated.

FIG. 13 presents results of simulations of optical absorbance for cross pattern nanopattern with dimensions of FIG. 9A, on Ag substrate, as shown in inset, for various depths as indicated. The two extreme situations are sketched.

FIG. 14 illustrates a fabricated cross pattern (total area 1.2 mm×1.2 mm), under several different magnifications, designed to mimic the cross-shaped nanopattern.

FIG. 15 illustrates an apparatus for measuring 0^{th} order reflection and transmission of small area samples. Fiber is placed against sample over area to be measured.

FIG. 16 presents experimental 0^{th} order absorbance for the sample described in the text. The enhancement of long wavelength absorption in this sample, comprised of subwavelength-dimensioned Ag crosses of FIG. 15, is evident.

FIG. 17A illustrates measured light absorbance results for 50 mm-thick Ag nanohole array embedded in 80 mm thick amorphous silicone for various embedded depths.

FIG. 17B illustrates simulated light absorbance results for 50 mm-thick Ag nanohole array embedded in 80 mm thick amorphous silicone for various embedded depths.

FIG. 18 illustrates simulated power loss density results for a cross shaped nanostructure assembled from insulated nanoparticles.

FIG. 19 illustrates simulated power loss density results for a triangle shaped unibody nanostructure with an insulating coating.

FIG. 20A illustrates an embodiment of embedded metal nanopattern (EMN) scheme utilized in Example 11, with cross-section of idealized absorber structure having integrated Ag (gray) EMN in a-Si (red), with cross EMN.

FIG. 20B is a close up of a unit cell of the EMN of FIG. 20A.

FIG. 21A, FIG. 21B and FIG. 21C illustrate simulated absorbance A within a-Si while tuning the embedding depth d of a Ag cross EMN for normally-incident, linearly polarized light (50 nm FTO, 60 nm a-Si and 20 nm EMN thicknesses). FIG. 21A is a plot of absorbance versus free-space wavelength for various d, for EMN placement between on-the-top (d≦−20 nm) and on-the-bottom (d≧+40) contacts, showing strong near infrared enhancement. FIG. 21B is a contour plot of absorbance data in (a) on linear 0-1 color scale, highlighting the optimum embed depth regime. FIG. 21C illustrates absorbance enhancement at fixed wavelengths vs. embed depth d, relative to an EMN-free control sample, showing strongest effects at long wavelengths (>300% at 800 nm) (left scale) and variation in calculated short circuit current density with d, relative to the control, showing maximum ˜70% increase near d=15 nm (right scale).

FIG. 22 illustrates simulated power loss density at λ=700 nm linearly polarized (Eₓ) incidence for the Ag cross EMN, viewed in y-z-plane cross-sections cut through the middle of two unit cells, for various embed depths d. The light-sample coordinate system is indicated, and only the FTO and a-Si layers are shown, with the EMN indicated by its outline. The 0-5×10⁻¹⁰ W/m³ linear color scale is shown. On the right is a series of x-y slices of the d=20 nm depth P̅_{L} at different z-positions, providing a separate perspective of the spatial distribution of electromagnetic absorption, which is primarily in the a-Si.

FIG. 23 illustrates results of simulations utilizing an embodiment of an embedded metallic nanopattern and an embodiment of an embedded dielectric nanopattern.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

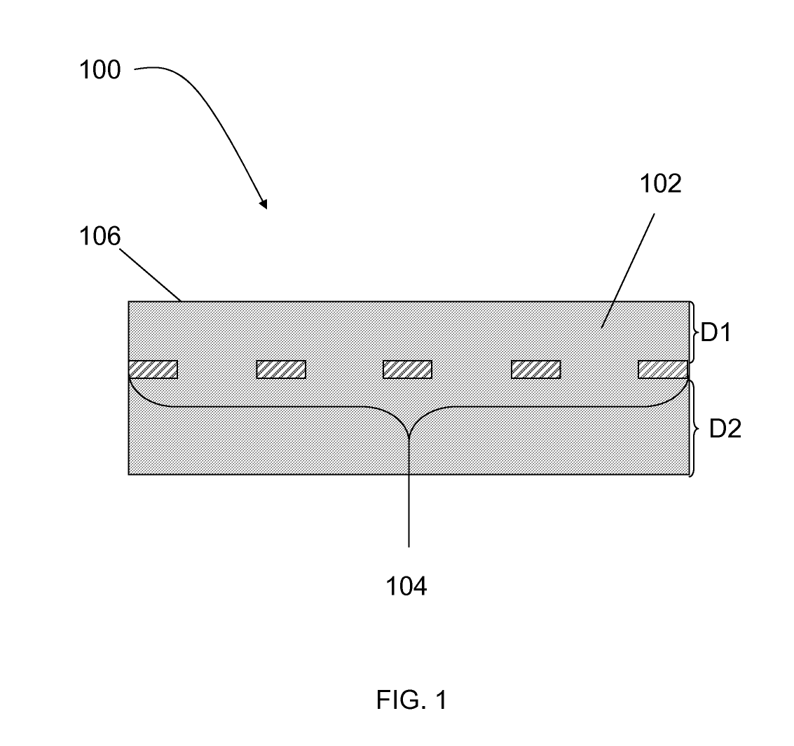

The present disclosure provides a light absorbing layer for a photovoltaic junction that is highly absorptive of incident light, including in the visible spectrum. In reference to FIG. 1, the light absorbing layer 100 includes a light absorbing material 102 with a nanopattern 104 embedded within the light absorbing material 102. In some embodiments, the nanopattern may be metallic, and thus can be referred to as an embedded metallic nanopattern (EMN.)

The nanopattern 104 is positioned within the light absorbing material at a distance D1 from a light absorbing or front surface 106 of the light absorbing material 102 and a distance D2 from a back surface 106 of the light absorbing material 102. The distances D1 and D2 may range between about 0 and about 50 nm, independently of each other. In some embodiments, the distance D1 between the front surface of the nanopattern 104 and the light absorbing surface 106 of the light absorbing material 102 is between about 0 nm and about 30 nm. In some embodiments, the distance D1 between the front surface of the nanopattern 104 and the light absorbing surface 106 of the light absorbing material 102 is between about 5 nm and about 30 nm. In some embodiments, the distance D1 is between about 0% and about 80% of the thickness of the light absorbing material. In some embodiments, the distance D1 is between about 2.5% and about 60% of the thickness of the light absorbing material. In some embodiments, the distance D1 is between about 2.5% and about 50% of the thickness of the light absorbing material. In some embodiments, the distance D1 is between about 5% and about 60% of the thickness of the light absorbing material. In some embodiments, the distance D1 is between about 5% and about 50% of the thickness of the light absorbing material. In some embodiments, the distance D1 is between about 10% and about 50% of the thickness of the light absorbing material. In some embodiments, the distance D2 between the back surface of the nanopattern 104 and the back surface of the light absorbing material 102 is between about 0 nm and about 20 nm. In some embodiments, both D1 and D2 are non-zero. In some embodiments, the distance D2 between the back surface of the nanopattern 104 and the back surface of the light absorbing material 102 is between about 5 nm and about 20 nm.

In some embodiments, the thickness of the nanopattern 104 is between about 10 nm and about 50 nm. It will of course be understood that the sum of the distance D between the nanopattern 104 and the light absorbing surface 106 of the light absorbing material 102 and the thickness of the nanopattern 104 is less than the thickness of the light absorbing material 102.

The nanopattern 104 can enhance the total absorption of light energy by the light absorbing material 102 by increasing the local electric field intensity in the vicinity of the nanopattern 104, which can be aided by plasmonic effects. On the other hand, the EMN themselves show a low level of light absorption. When the nanopattern 104 is exposed to light energy, surface plasmons may be generated at the boundary of the nanopattern, thereby generating an electric field in the light absorbing material 102 extending for a distance away from the nanopattern 104. Prior approaches that employ metal nanopatterns or nanoparticles as front or back scatterers only capitalize on a portion of the concentrated electromagnetic field around the metal patterns. Embedded metal nanopatterns were believed to increase recombination of photogenerated electron-hole pairs, and thus depress photovoltaic efficiency. Meanwhile, embedded dielectric nanoparticles are rather weak scatterers of optical electromagnetism. Embedding a nanopattern entirely within the light absorbing material, however, may allow exploitation of the strong scattering from the nanopattern as well as potentially harvesting increased amounts of the scattered light by the embedded nanopattern 104. As a result, the number of photogenerated electron-hole pairs in the light absorbing material can be increased.

In some embodiments, the light absorbing material 102 is a semiconductor material. In some embodiments, the light absorbing material may be any semiconductor material that exhibits the photovoltaic effect, including, but not limited to, silicon, germanium, selenium, cadmium telluride, iron sulfide, copper sulfide, copper indium selenide, copper indium sulfide, copper indium gallium selenide, gallium arsenide and similar, as well as a number of organic photoabsorber materials. In some embodiments, the light absorbing material may exhibit effect other than a photovoltaic effect, in addition or instead of a photovoltaic effect. The light absorbing material may be crystalline or amorphous. In some embodiments, the light absorbing material is selected from amorphous, protocrystalline, nanocrystalline, monocrystalline or polycrystalline silicon. In some embodiments, the light absorbing material is a thin semiconductive film. In some embodiments, the light absorbing material is thin film of amorphous silicon. In some embodiments, the thickness of the light absorbing material 102 is between about 10 nm to about 100 nm. In some embodiments, the thickness of the light absorbing material 102 is between 10 and 50 nm. In some embodiments, the light absorbing material may be a material capable of absorbing electromagnetic radiation in infrared, visible, and ultraviolet spectrum. In some embodiments, the light absorbing material may include non-photovoltaic light absorbing materials.

In some embodiments, the nanopattern is formed from metallic nanostructures. Suitable metallic materials for nanopatterns include, but are not limited to, to silver (Ag), aluminum (Al), gold (Au), chromium (Cr), copper (Cu), platinum (Pt), other similar metals or combinations thereof. It should be noted however that nanostructures may be produced from non-metallic materials as well. In some embodiments, the nanostructures may be formed from a dielectric material. In yet other embodiments, the nanopattern may include both metallic nanostructures and non-metallic nanostructures.

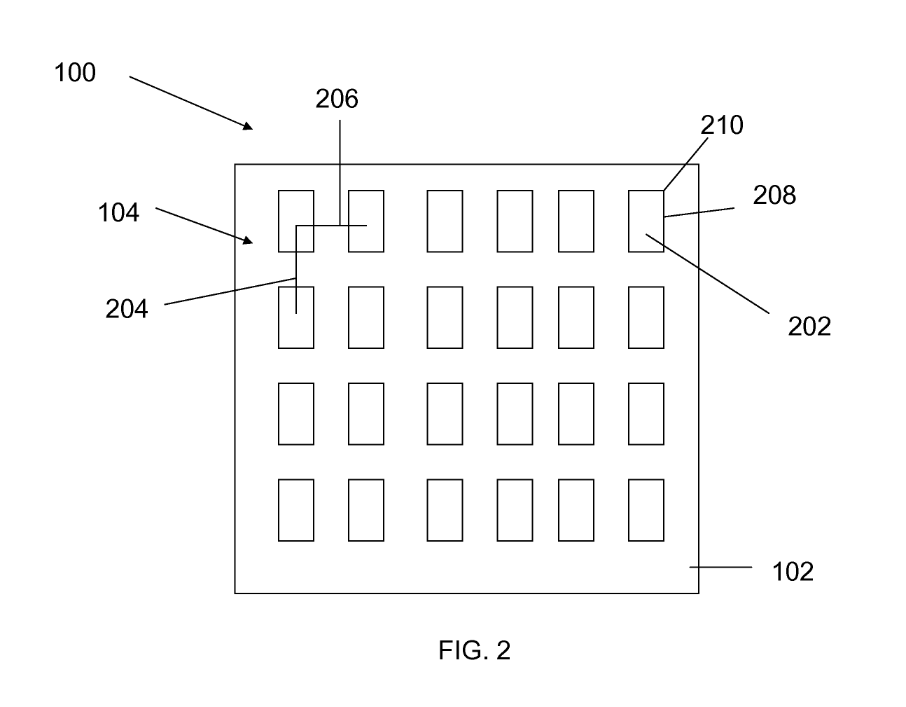

FIG. 2 is a top view of an embodiment of the light absorbing layer 100 with the nanopattern 104 embedded in the light absorbing material 102. The nanopattern 104 comprises a planar array of nanostructures 202. The absorbance enhancement provided by the nanopattern scheme can depend quantitatively (as well as qualitatively) on the precise pattern, so that a certain amount of tolerance exists for the nanopattern shape details.

In some embodiments, the nanostructures 202 have subwavelength dimensions. The term “subwavelength” as used herein to refer to a dimension of a nanostructure means that the longest dimension of the nanostructure is less than the wavelength of the light to be absorbed by the light absorbing layer 100. In some embodiments, the dimensions of the nanostructures 202 are less than about 2000 nm. In some embodiments, the dimensions of the nanostructures 202 are less than about 1000 nm. In some embodiments, the dimensions of the nanostructures 202 are less than about 800 nm. In some embodiments, the dimensions of the nanostructures 202 are less than about 700 nm. In some embodiments, the dimensions of the nanostructures 202 are less than about 600 nm. In some embodiments, the dimensions of the nanostructures 202 are between about 20 nm and about 800 nm. In some embodiments, the dimensions of the nanostructures 202 are between about 20 nm and about 700 nm. In some embodiments, the dimensions of the nanostructures 202 are between about 20 nm and about 600 nm. In some embodiments, the dimensions of the nanostructures 202 are between about 100 nm and about 300 nm.

The nanostructures 202 are arranged at a desired pitch. The term “pitch” refers to the distance 204 between central points of adjacent nanostructures 202 in a row, as well as the distance 206 between central points of adjacent nanostructures 202 in a column. In some embodiments, the pitch is less than about 2000 nm. In some embodiments, the pitch is less than about 1000 nm. In some embodiments, the pitch is between about 50 nm and about 800 nm

The distances 204, 206 can be uniform or non-uniform. In some embodiments, the pitch of the planar array is subwavelength, that is, the longest distance 204, 206 between adjacent nanostructures is less than the wavelength of the light to be absorbed by the light absorbing layer 100.

The nanostructures 202 may be of any shape. In some embodiments, the nanostructures 202 are provided with at least one substantially straight or sharp edge 208. In some embodiments, the nanostructures 202 are provided with at least one substantially sharp corner 210. In some embodiments, the nanostructures 202 are provided with at least one edge sufficiently straight to increase electrical filed generated at the interface of the nanopattern 104 and the light absorbing material 102. In some embodiments, the nanostructures are provided with a multitude of length scales that may lead to a broadband scattering response. In some embodiments, the nanostructures 202 can be a polygon, including, but not limited to, circles, ellipses, stars, squares, rectangles, triangles, quasi-triangles, cross-shaped, isosceles trapezoid or similar.

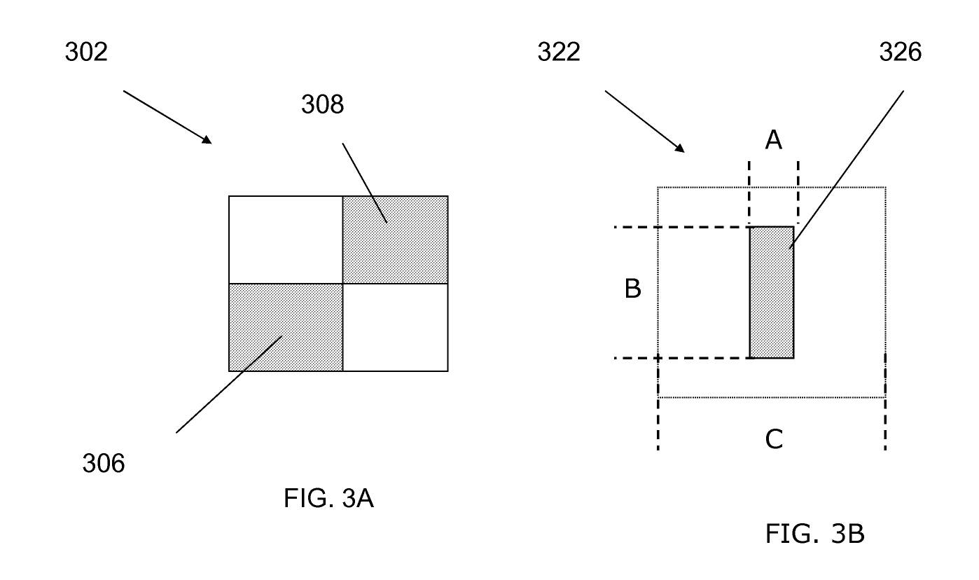

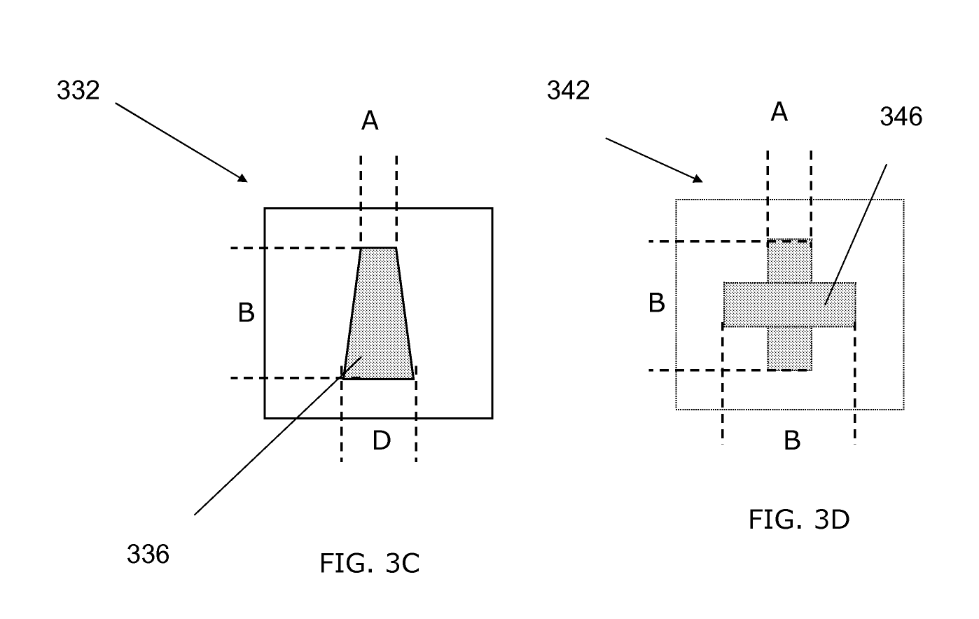

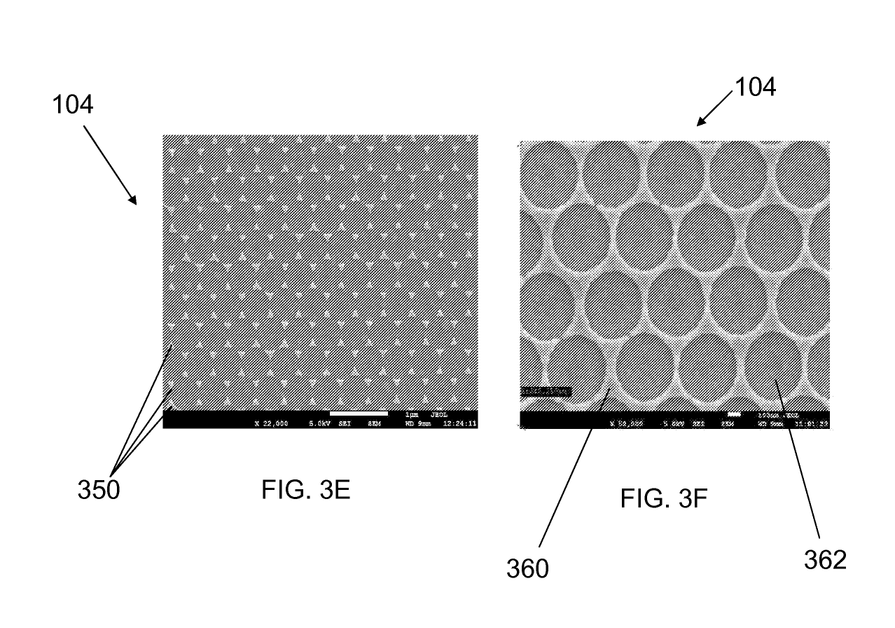

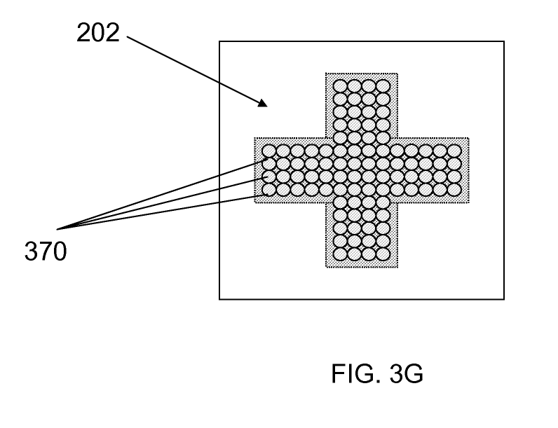

FIGS. 3A-3F illustrate non-limiting examples of nanostructures 202 for the nanopattern 104 of the present disclosure. FIG. 3A illustrates a nanopattern unit cell 302, where the nanostructure 202 is alternating squares 306 and 308. In some embodiments, the nanopattern unit cell 302 has about 400 nm sides and the squares 306, 308 have about 200 nm sides. FIG. 3B illustrates a nanopattern unit cell 322, where the nanostructure 202 is a rectangle 326. In some embodiments, the nanopattern unit cell 322 has sides of length C ranging between about 100 to about 800 nm sides C and the rectangle 326 has a to width A of about 10 to about 100 nm and a length B between about 20 nm and about 200 nm. FIG. 3C illustrates a nanopattern unit cell 332, where the nanostructure 202 is an isosceles trapezoid 336. In some embodiments, the nanopattern unit cell 332 has sides of length C ranging between about 100 about 800 nm and the isosceles trapezoid 336 has parallel sides of length A and D ranging between about 10 to about 100 nm and about 20 to about 100 nm, respectively, and opposite sides of length B ranging between about 20 nm and about 200 nm. FIG. 3D illustrates a nanopattern unit cell 342, where the nanostructure 202 is a symmetric cross 346. In some embodiments, the nanopattern unit cell 344 has sides of length C ranging between about 100 to about 800 nm and the cross 346 has arms of length A ranging between about 10 to about 100 nm and a span B ranging between about 20 nm and about 200 nm. In some embodiments, the nanopattern unit cell 342 has about 630 nm sides and the cross 346 has about 200 nm arms and 500 nm span.

The nanostructures 202 may be interconnected with one another or may be separated from one another. FIG. 3E illustrates an embodiment of the nanopattern 104, where the nanostructures 202 are separated triangles 350. FIG. 3F illustrates an embodiment of the nanopattern 104, where the nanostructures 202 are interconnected triangles 360, or quasi-triangles. It should be noted that the nanopattern 104 may be described in terms of nanovoids instead of nanostructures 202. For example, the embodiment of the nanopattern 104 shown in FIG. 3F can be alternatively described as an array of interconnected nanostructures 200 in the shape of triangles 360 or as an array of substantially circular nanoholes 362.

FIGS. 3A-3G illustrate examples of unibody nanostructures. Alternatively, in some embodiments, as shown in FIG. 3G, the nanostructures 202 of the nanopattern 104 can be assembled from a plurality of nanoparticles 370, such as metal nanoparticles.

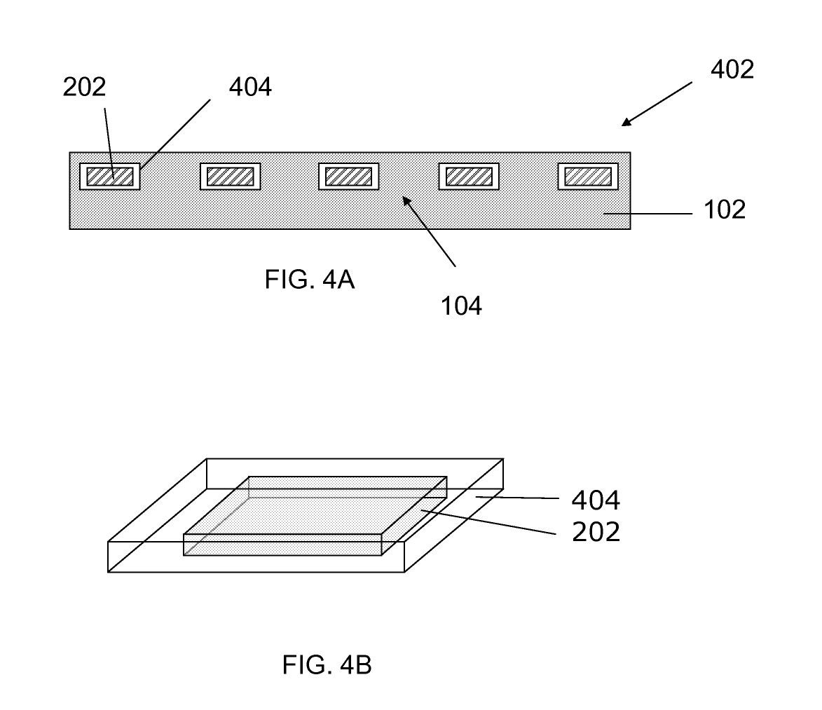

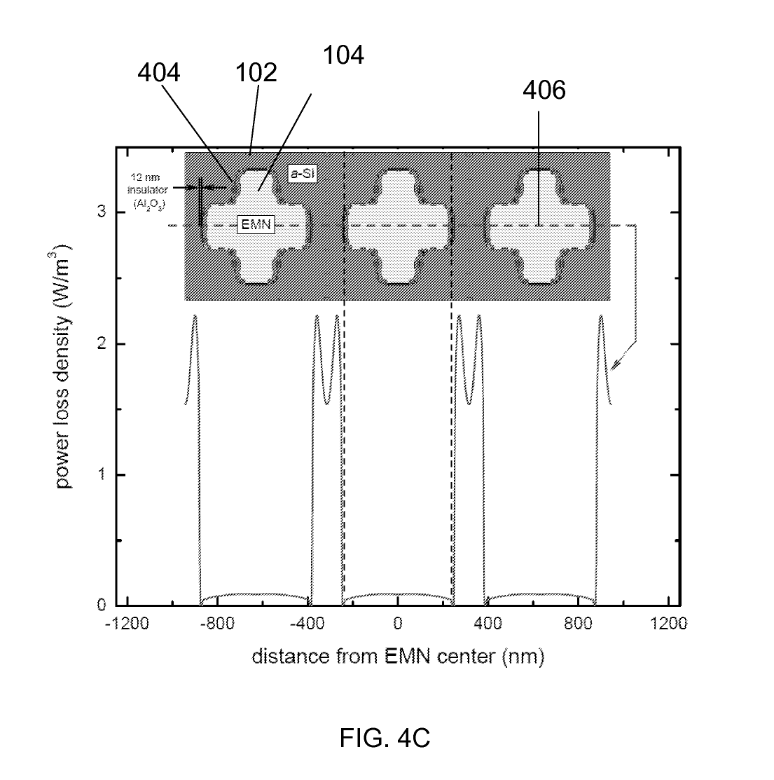

In some embodiments, as shown in FIG. 4A and FIG. 4B, nanostructures 202 of a light absorbing layer 402 are encapsulated in an insulating coating 404. Suitable insulating materials include, but are not limited to, aluminum oxide, silicon oxide, silicon nitride, and a nonconducting polymers. In some embodiments, the insulating coating 404 can be applied to already assembled nanostructures 202 of nanopatterns 104. Alternatively, the nanostructures 202 or nanopatterns 104 may be fabricated from materials insulated with the insulating coating 404.

In some embodiments, the insulating coating 404 is sufficiently designed to decrease or prevent electron-hole recombination on the surfaces of the nanostructures 202. In some embodiments, the insulating coating 404 is sufficiently designed to avoid electron tunneling between the light absorbing material 102 and the nanopattern 104.

In some embodiments, the thickness of the insulating coating 404 is such that enhanced electric field due to the surface plasmons generated at the boundary of the nanopattern extends outside the insulating coating 404. In some embodiments, the thickness of the insulating coating is between about 10 nm and about 50 nm. In some embodiments, the thickness of the insulating coating 404 can be determined according to the following formula: I=Io e^{-x/a}, where I is electron/hole tunneling current, x is the thickness of the insulating coating, a is about 1-5 nm and Io is the current in the absence of an insulating coating. In some embodiments, the insulating coating 404 is simultaneously thicker than the electron or hole characteristic tunneling length (“a” in the above equation), and thinner than the electric field decay length “b” in the equation E=Eₒ e^{-x/b}, where Eₒ is the electric field at the surface of the nanopattern (x=0) and x is the distance into the light absorbing material from the surface of the nanopattern. Because, in some embodiments, the thickness of the insulating coating 404 is such that enhanced electric field extends outside the insulating coating 404, strong absorption in the light absorbing material 102 persists in the presence of the insulating coating 404, as shown in FIG. 4C. As can be seen from FIG. 4C, the absorption, which is proportional to “power loss density,” inside the nanopattern 104 and the insulating coating 404 is lower than the absorption in the light absorbing material 102. The broken line 406 in FIG. 4C cut across the middle of 3 units shows that the absorption inside the metal part (marked “EMN”) is low and the absorption in the amorphous silicon (“a-Si”) is high, in the case where there is a thin insulating coating 404.

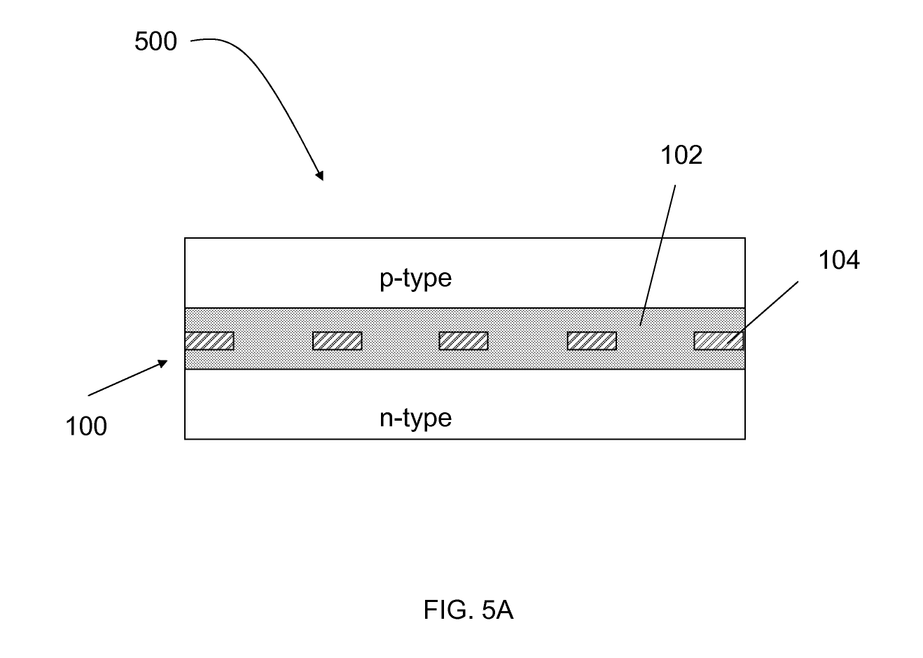

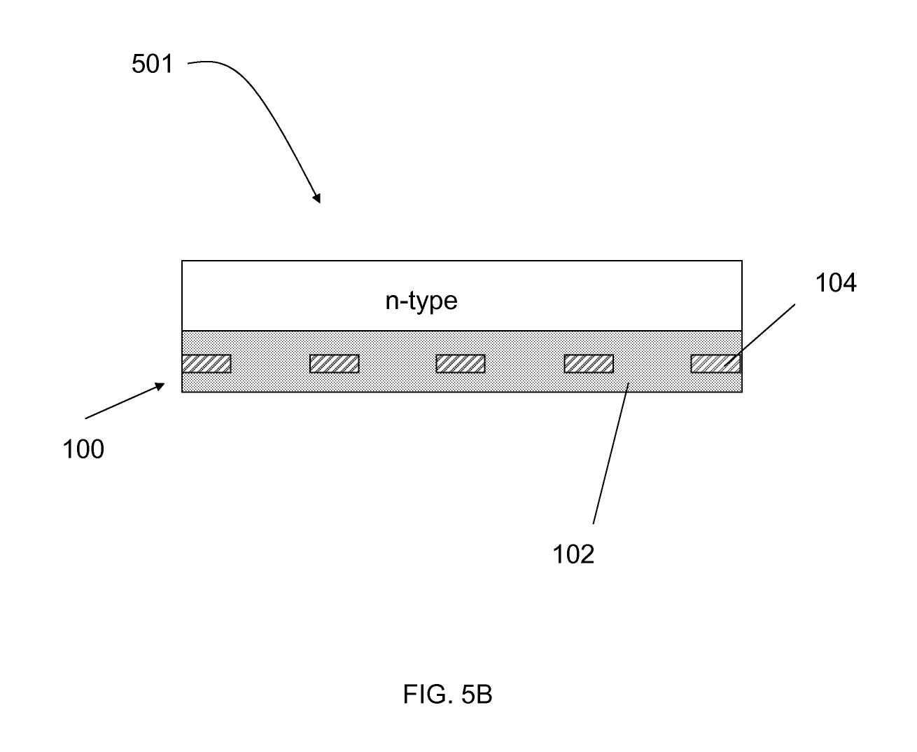

In another aspect, shown in FIG. 5A and FIG. 5B, the present disclosure provides a photovoltaic junction that includes a light absorbing layer 100 of a light absorbing material 102 having a nanopattern 104, such as a metallic nanopattern, embedded therein. The photovoltaic junction of the present disclosure can be either a p-i-n junction 500 or a p-n junction 501, as shown in FIGS. 5A and 5B, respectively. Depending on the type of the photovoltaic junction to be formed, the light absorbing material 102 of the light absorbing layer 100 can be a p-type material, n-type material or i-type material.

In reference to FIG. 5A, in some embodiments, the photovoltaic junction 500 is an amorphous silicon (a-Si) p-i-n junction, wherein the light absorbing layer 100 of the present disclosure forms the i-region. That is, the nanopattern 104 is embedded in the i-region of the photovoltaic junction 500. In other embodiments of the p-i-n photovoltaic junction 500, the nanopattern 102 can be embedded into the p-region, the n-region or both, in addition to or instead of the i-region.

In reference to FIG. 5B, in some embodiments, the photovoltaic junction 501 is a p-n junction, wherein the light absorbing layer 100 of the present disclosure forms the p-region and the top layer, or “window” layer, is the n-region of the photovoltaic junction 501. It should be noted, however, that although illustrated as the p-layer of the photovoltaic junction, the light absorbing layer of the present disclosure can also be the n-region, depending on whether the p-region or the n-region is the light absorbing layer of the photovoltaic junction 501. Other possible embodiments of p-n photovoltaic junctions include p-region as the top layer with embedded nanopattern and n-region without embedded nanopattern, p-region as the top layer with embedded nanopattern and n-region with embedded nanopattern, n-region as the top layer with embedded nanopattern and p-region without embedded nanopattern, and n-region as the top layer with embedded nanopattern and p-region with embedded nanopattern.

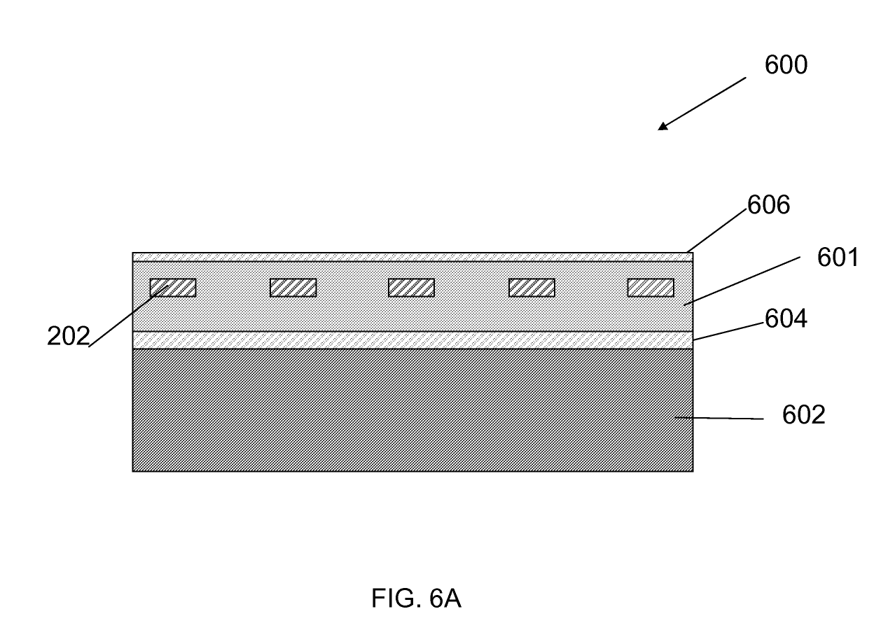

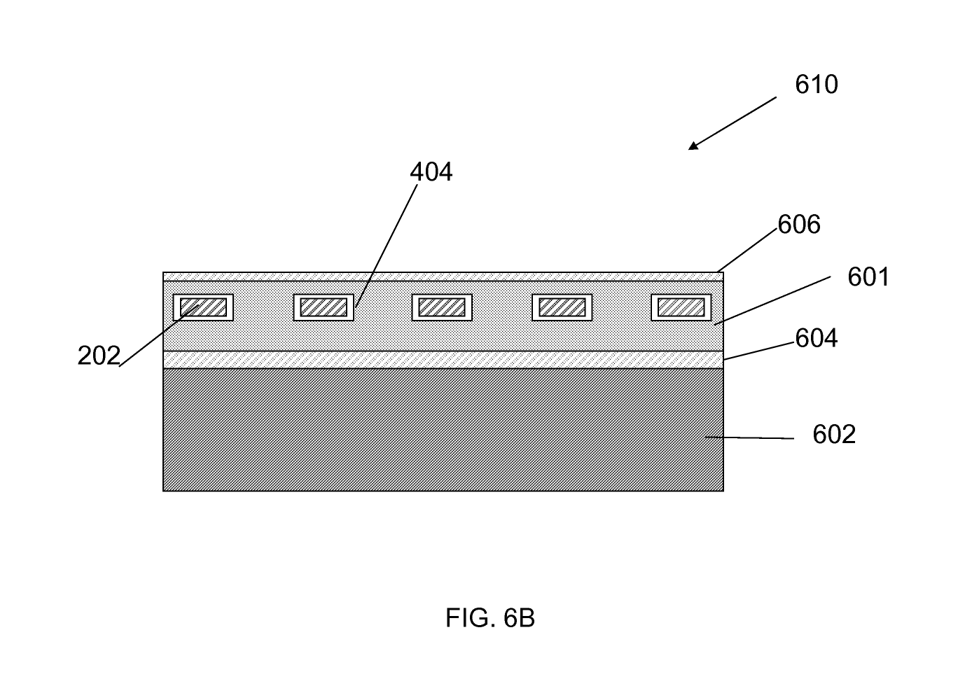

In another aspect, there is provided a solar cell fabricated using a photovoltaic junction of the present disclosure. As illustrated in FIG. 6A, in some embodiments a solar cell 600 of the present disclosure generally comprises a photovoltaic junction 601, which can be either a p-i-n junction 500 or a p-n junction 501 having a light absorbing layer 100 of a light absorbing material 102 with a nanopattern 104, such as a metallic nanopattern, embedded therein. The photovoltaic junction 601 is deposited on a substrate 602. Suitable materials for the substrate include, but are not limited to, glass, such as borosilicate glass; polymers, such as SU-8, polyimide, polyethylene naphthalate (PEN), polyethylene terephthalate (PET), or metals, such as stainless steel or aluminum. The solar cell 600 also includes a front electrical contact 606 disposed on the front surface of the photovoltaic junction 601 and a rear contact 604 disposed between the substrate 602 and the photovoltaic junction 601. In some embodiments, the front electrical contact 606 is a transparent conductor, such as a transparent conducting oxide layer (TCO), such as indium tin oxide and the rear contact 604 is a metallic contact or TCO. However, other materials can also be used for the front and rear contacts 604, 606. In some embodiments, the solar cell 600 can also include an anti-reflective coating and a protective encapsulant. In some embodiments, the solar cell 600 includes multiple layers of the same or different embodiments of the photovoltaic junctions 500 stacked one on top of another. FIG. 6B, illustrates a solar cell 610, where the nanostructures 202 are enclosed with the insulating coating 404.

In another aspect, there is provided a method for fabricating a solar cell with a p-i-n photovoltaic junction that includes a light absorbing layer 100 of a light absorbing material 102 having a nanopattern 104 embedded therein. Initially, a back layer of the photovoltaic junction is formed by depositing a first type photovoltaic material over a rear contact on a substrate. In some embodiments, the first type photovoltaic material can be either a p-type or a n-type. The deposition of a light absorbing material onto the substrate may be achieved using any known technique in the art. In some embodiments, the light absorbing material may be deposited on the substrate using a chemical vapor deposition method (CVD). In CVD, gaseous mixtures of chemicals are dissociated at high temperature (for example, CO₂ into C and O₂). This is the “CV” part of CVD. Some of the liberated molecules may then be deposited on a nearby substrate (the “D” in CVD), with the rest pumped away. Examples of CVD methods include but not limited to, “plasma enhanced chemical vapor deposition” (PECVD), “hot filament chemical vapor deposition” (HFCVD), and “synchrotron radiation chemical vapor deposition” (SRCVD).

Next, a light absorbing layer of the present disclosure can be formed from a light absorbing material. In this instance, the light absorbing material is an i-type material. The first step of forming the light absorbing layer is depositing a first thickness of the light absorbing material over the back layer formed from the first type photovoltaic material. In some embodiments, the first thickness depends on the final thickness of the light absorbing layer, the thickness of a metal nanopattern to be embedded within the light absorbing layer, the distance from the top surface of the light absorbing layer to the nanopattern, or combinations thereof.

The second step of forming the light absorbing layer is creating a nanopattern 104 on the exposed surface of the light absorbing material. In some embodiments, the nanopattern 104 may be fabricated by electron beam lithography. In some embodiments, the nanopattern 104 may be fabricated by nanosphere lithography. By way of a non-limiting example, micro- or nanoscale spheres (or perhaps other shapes) may be assembled or self-assemble into an array at the surface of a liquid, with this array directly transferred to a photovoltaic material to be used as a lithography mask. Depositing nanopattern material (i.e. material from which nanostructures are made) onto a photovoltaic material covered with an array of these spheres yields an array of quasi-triangles of nanopattern material on the photovoltaic material below, such as for example, shown in FIG. 3E. In some embodiments, the radii of the spheres can be reduced while on the photovoltaic material before metal deposition, e.g. by etching, metal film can be prepared interspersed with nanoscale voids, with some degree of tunability, such as for example shown in FIG. 3F. That is, the hole radius can be tuned from 0 (fully etched) to its initial value (unetched). The metal network can be then deposited at controlled depth in the light absorbing layer, with the total thickness of the light absorbing layer fixed. In reference to FIG. 3E, the nanopattern was prepared by self-assembling spheres of about 500 nm initial diameter in an array atop an a-Si photovoltaic material, and depositing about 50 nm of metal (such as Ag) before removal of the spheres. In reference to FIG. 3F, the nanopattern was prepared by etching the spheres of about 500 nm initial diameter in an array atop of an a-Si photovoltaic material to about 400 nm diameter before metal deposition. Removal of the spheres leaves behind the nanostructures 202 that form the nanopattern 104. In some embodiments, polystyrene spheres can be used. Other techniques known in the art may be used to prepare the nanopattern 104 of the present disclosure.

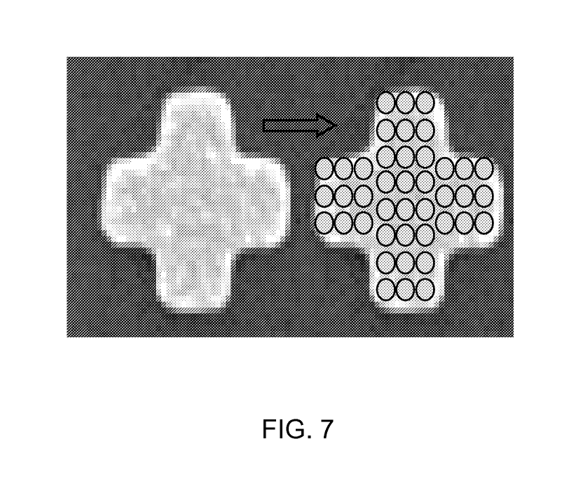

In some embodiments, the nanostructures making up the nanopattern can be insulated with an insulating coating. In some embodiments, the nanopattern 104 can be fabricated from nanostructures 202 without insulation onto which insulating coatings can be applied. In some embodiments, the nanopattern 104 can be assembled from already insulated materials. In some embodiments, the nanopattern 104 can include nanostructures 202 assembled from insulated metal nanoparticles. By way of a non-limiting example, soft lithographic techniques can be used to build such nanopatterns 104. In reference to FIG. 7, a nanopattern including cross-shaped nanostructures can be assembled from insulated metal nanoparticles. Nanopatterns built up from such nanoparticles can be prepared by a contact transfer technique whereby a hard 3D “stamp” containing a raised pattern of the desired structure (e.g. an array of crosses) is fabricated by nanolithographic techniques. The stamp can then be conformally coated with insulated nanoparticles (e.g. the spheres in FIG. 7), and brought in contact with a PV (such as a-Si) film of defined thickness, so that the cross pattern can be transferred to the PV film. A second PV coating is deposited over the nanopattern to complete the embedding process.

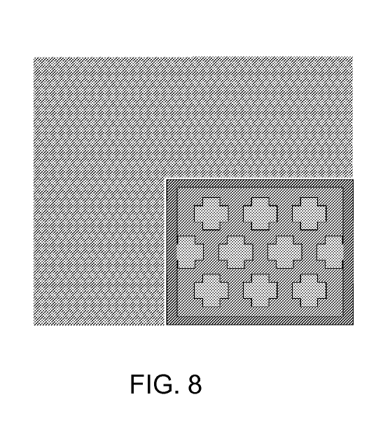

FIG. 8 illustrates an embodiment of a stamp 800 suitable in the presently disclosed methods, the stamp 800 representing a stamp with the nanopattern in 3D relief. The stamp 800, having nanoscale features, can be prepared by known lithographic techniques, including, but not limited to, e-beam lithography augmented by CMOS-style stepping technology for large areas, and nanoimprint lithography for facile stamp replication, as well as similar techniques.

In some embodiments, the nanopattern 104 with insulated nanostructures can be formed from fully insulated nanostructures that can themselves be patterned. By way of a non-limiting example, insulated nanostructures of a desired shape and ranging in size between about 50 to about 150 nm on a side can be substantially uniformly dispersed by simple spin coating onto a photovoltaic material.

The final step for forming a light absorbing layer of the present disclosure is to deposit a second thickness of the light absorbing material over the nanopattern. In some embodiments, the second thickness is the desired distance D between the top surface of the light absorbing layer and the metal nanopattern.

In the case of a p-i-n photovoltaic junction, once the light absorbing i-layer is formed, a front layer of the photovoltaic junction can be formed by depositing a second type photovoltaic material (n-type or p-type) over the light absorbing layer. The second type photovoltaic material has a charge opposite to the charge of the first type photovoltaic material. Finally, a front contact and, optionally, an antireflective coating, encapsulant or any other elements can be added to the solar cell. It should be noted that although the method for fabricating solar cells of the present disclosure is described and illustrated in the present disclosure in connection with fabricating a solar cell with a p-i-n photovoltaic junction, the methods disclosed herein are equally applicable for fabricating a solar cell with a p-n junction. It will be understood that, if fabricating a solar cell with a p-n junction, the light absorbing material has a dopant valence opposite to the dopant valence of the first type photovoltaic material and the light absorbing layer is deposited over a substrate first.

### EXAMPLES

Examples (actual and simulated) of using the devices and methods of the present disclosure are provided below. These examples are merely representative and should not be used to limit the scope of the present disclosure. A large variety of alternative designs exists for the methods and devices disclosed herein. The selected examples are therefore used mostly to demonstrate the principles of the devices and methods disclosed herein.

### Example 1

### Simulations

Simulations were performed on an 8-core CPU PC with a 448-core GPU using CST Microwave Studio. Simulations for two different nanopatterns embedded at various depths in thin a-Si films were performed in the time domain using the finite integration technique (FIT). Full dispersion relations, obtained from ellipsometry experiments on a-Si, and from standard literature sources for the metals, were employed in all simulations.

### Example 2

### Alternating Square Nanopattern on ITO-Glass Simulation

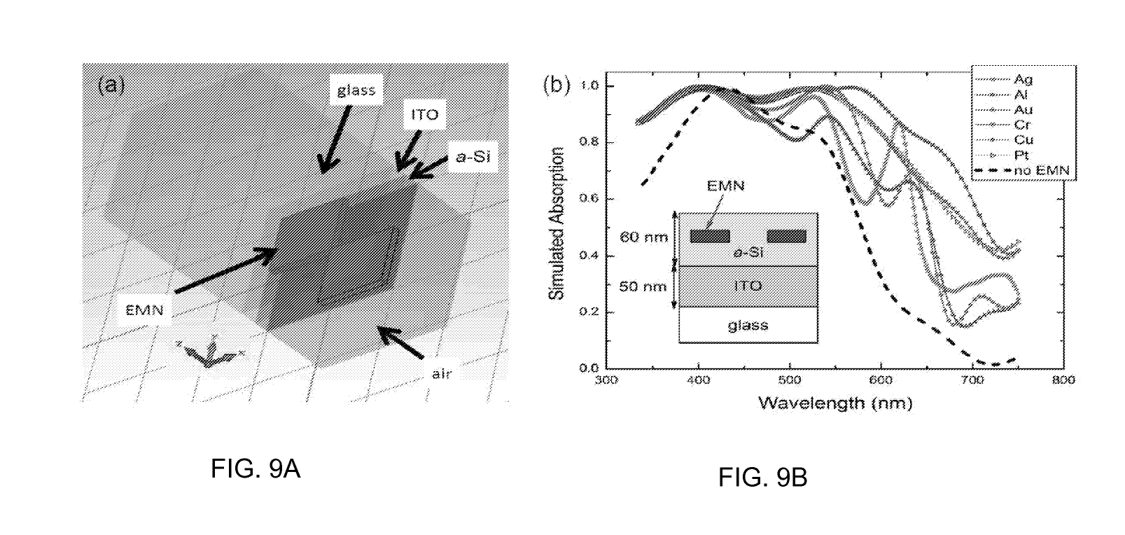

As illustrated in FIG. 9A and FIG. 9B, a unit cell of an alternating square nanopattern measures 400 nm on a side, with a metal pattern consisting of 200 nm metal squares in an alternating square pattern, with the plane of the structure aligned to the x & y axes of the coordinate system and the z-axis normal to the plane of the pattern. Optical absorption A was simulated for this pattern, using periodic boundary conditions on the unit cell in the x and y directions, and with a plane electromagnetic wave of variable wavelength impacting the system along the z direction. The periodic boundary conditions allow the simulation to represent a large (infinite) array of such patterns in the x and y directions. Reflection and transmission of the incident plane wave normal to the z-axis were simulated, thus simulating 0^{th} order reflection R and transmission T, yielding absorbance/absorption via A=1−R−T.

FIG. 9A is an illustration of the 400 nm×400 nm unit cell for simulations of an infinite array of metallic squares embedded in an a-Si absorber layer in an alternating square pattern (EMN). FIG. 9B is a graph of simulated optical absorbance of the structure for various metals, for light incident from the glass side. Similar results are obtained for light incident from the vacuum side. The simulated layer thicknesses were: 50 nm ITO, 60 nm a-Si, 500 nm glass, 20 nm EMN, with the EMN embedded by a distance of 25 nm into the a-Si below the glass surface. It should be noted that this EMN structure had a noticeable effect on the absorption spectrum of the system, especially at the longer wavelengths.

It was found that the choice of metal and the details of the shape and placement of the metal can affect the absorption of light in these structures. In these simulations, the full dispersion relations of all of the materials were used, thus illustrating how sensitive the systems are to the detailed material properties of the constituents. Also shown for comparison is a film of a-Si with the same thickness as that used in the EMN absorption simulations, but without incorporation of an EMN. It can be seen that, for all metals employed, inclusion of the EMN significantly increased optical absorption, especially at longer wavelengths.

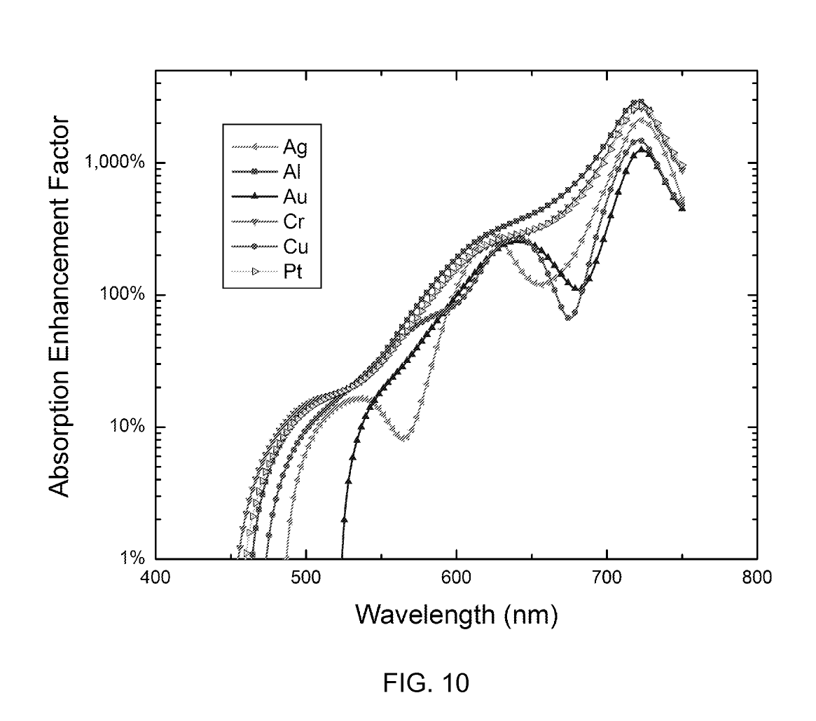

FIG. 10 is a plot of the absorption enhancement factor A(EMN)/A(a-Si), that is, the simulated absorption of the EMN structure relative to that in the same thickness a-Si without the EMN. FIG. 10 shows that the enhancement factor varies from about 10% improvement at 500 nm to over 1,000% improvement at 700 nm. This magnitude absorption increase is significant, given that at these lower energies/longer wavelengths, the majority of the metals depicted are highly reflecting (in bulk), rather than absorbing.

### Example 3

### Cross Nanopattern on ITO-Glass Simulation

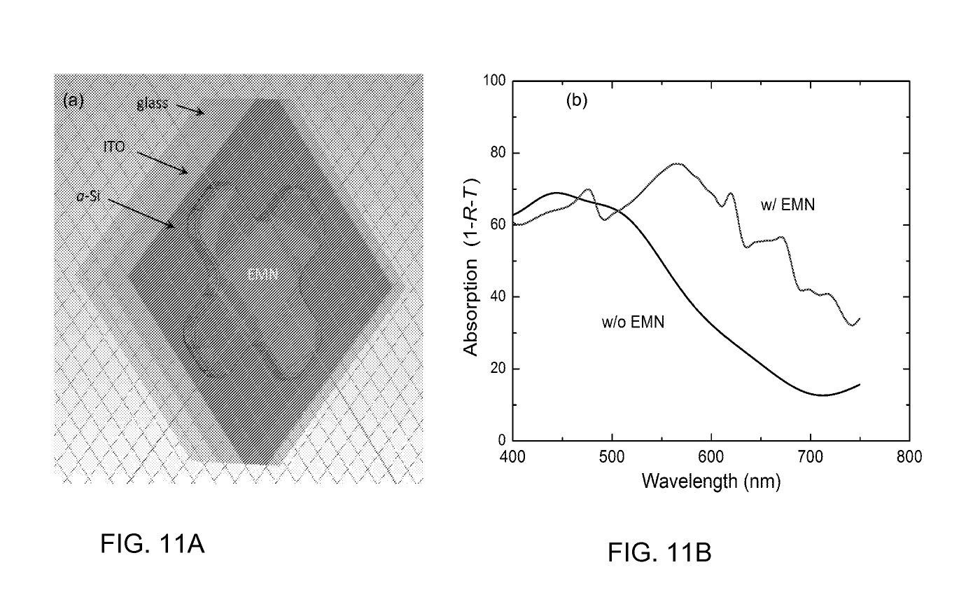

The second EMN pattern simulated was an array of subwavelength crosses, as depicted in FIG. 11A. A square unit cell with 630 nm sides contained a symmetric cross with 200×500 nm arms 35 nm thick. An array of this EMN was embedded 45 nm below the surface of an 80 nm-thick a-Si film, similar to the EMN in FIG. 11A. In addition, the inner and outer corners of this EMN structure were intentionally rounded, with a radius of curvature of 50 nm, to more closely approximate what one may be able to fabricate and test experimentally. The simulated absorption for this structure is shown in FIG. 11B, along with a control simulation for the same film sequence but without the EMN. Similarly to FIG. 9A and FIG. 9B, inclusion of the EMN enhances absorption, in the present case by more than 40%, integrated across the 400-750 nm wavelength regime.

### Example 4

### Alternating Square Nanopattern on Metal Substrate

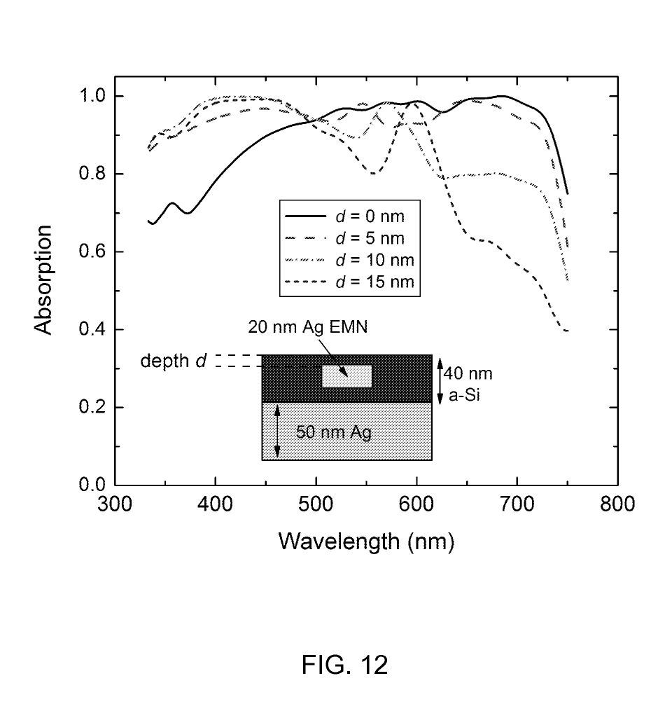

Simulations of an alternating square nanopattern arranged within a silicon film on a metallic (Ag) substrate were performed. This differs from the prior configuration in that the Ag film can act as a back-reflector, giving incident light up to two passes through the Si/EMN medium. As shown in FIG. 12, this configuration is a 40 nm total thickness a-Si film placed on a 50 nm-thick Ag film, with a 20 nm-thick alternating square EMN (with same lateral dimensions as the one in Example 2 (FIG. 9A) embedded at various depths d below the top a-Si surface. Here, d=0 refers to the top edge of the EMN being flush with the top edge of the silicon. Rather strong absorption (A>90%) results for wavelengths above 600 nm for this case, with this long-wavelength absorption diminishing as the EMN depth (d) increases. Meanwhile, once the EMN is fully buried (i.e. d>0), high energy/short wavelength light absorption notably increases, to over 90%.

### Example 5

### Cross Nanopattern on Metal Substrate

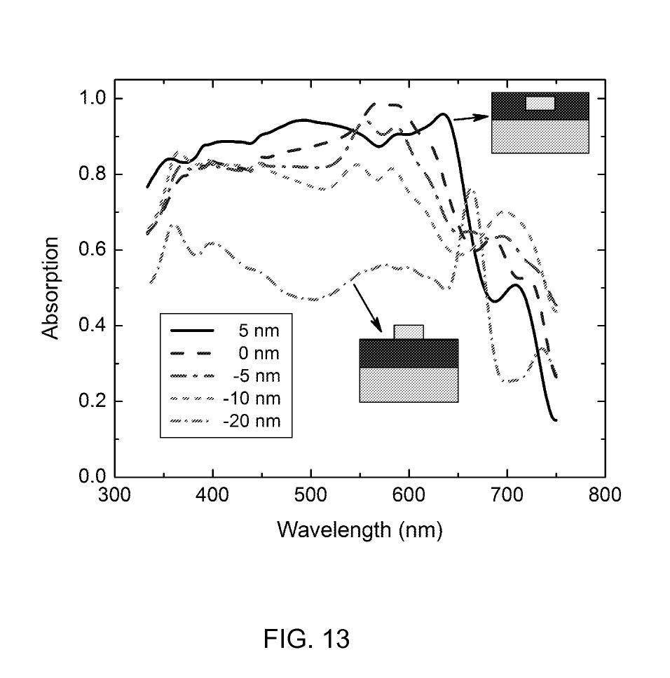

FIG. 13 shows absorption data for the cross-pattern EMN of Example 3 on a metal substrate, as in Example 4, for two EMN depths, d=0 and d=−20 nm (i.e. for the metal nanopattern situated on top of the Si film, rather than embedded). FIG. 13 demonstrates the potential advantage of embedded subwavelength nanostructures fully within the semiconductor absorber layer, as opposed to merely placing it on top. Absorbance between 80% and 95% is simulated/predicted for a mere 40 nm thick a-Si film, with integrated absorption (over the wavelength range shown) for the embedded case (d=5 nm) more than 60% larger than for the surface case (d=−20 nm).

### Example 6

### Experimental Methods

Test substrates were fabricated using commercial 0.7 mm thick glass substrates coated with 500 nm ITO, diced into 1 cm×2 cm coupons. Amorphous Si was deposited by plasma enhanced chemical vapor deposition (PECVD). The thickness of an initial a-Si layer depended on the distance the metal layer was to be embedded into the a-Si layer (including zero). The sample was removed from the PECVD chamber, and the metal pattern created by standard e-beam lithographic techniques. Two layers of poly(methylmethacrylate) (PMMA) were coated onto the ITO glass wafer. The first layer was PMMA 495 A4, spin coated for 60 s at 4000 rpm and hard baked for 20 min at 180 C; the second layer was PMMA 950 A4.5, spin coated for 60 s at 5000 rpm and hard baked for 20 min at 180 C. E-beam writing was done in a JEOL 7001 SEM system integrated with a Nabity nanometer pattern generation system e-beam writing code. The sample was then put back into the PECVD chamber and a-Si deposition resumed. As the area of the metal pattern was small, 2 mm×2 mm, compared to the coupon, the non-metalized areas served as optical measurement controls for areas with the nanopatterned embedded metal.

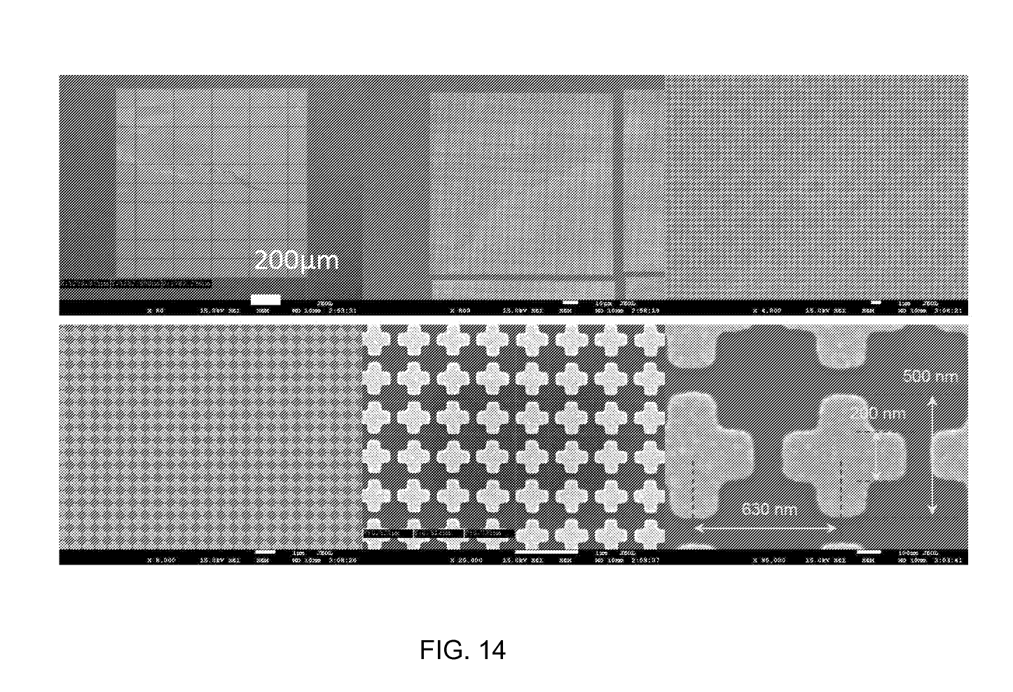

FIG. 14 shows an embodiment e-beam lithographed cross test pattern composed of 100 e-beam exposure fields, each 120 μm on edge, stitched together to form a 1.2 mm×1.2 mm test pattern. At the finest scale (lower right), the crosses deviate from the ideal crosses in that the corners show some rounding. The dimensions of this EMN are indicated in FIG. 14.

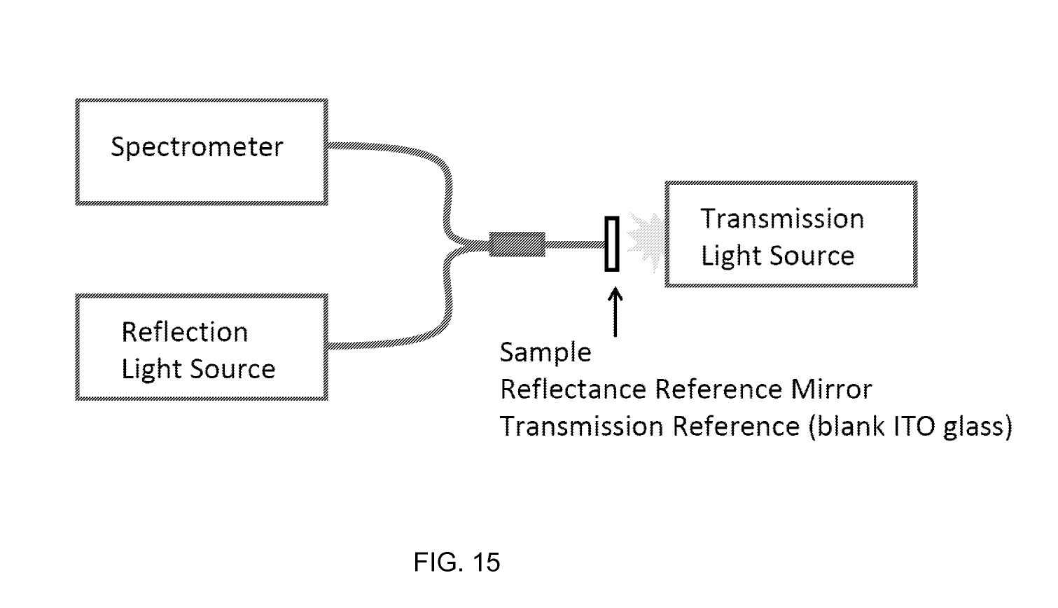

Optical measurements, both reflection and transmission, were performed using a modified fiber optic spectrometer from Ocean Optics which measures the 0^{th} order reflection R₀ and transmission T₀ of small sample areas (<200 μm diameter). The apparatus consisted of a bifurcated optical fiber, of which one arm was connected to the spectrometer and the other to a light source for reflectance measurements as shown in FIG. 15. For a reflectance measurement, the reflection source is lit, and spectra are taken of a front surfaced silver reference mirror which acts as the 100% reflecting standard, then the mirror is replaced by the sample. The sample spectra are normalized by the silver mirror spectra, thus producing a sample reflectance spectra that ranges from 0 to 100% reflectivity (as compared to the Ag reference).

For transmission measurements, the transmission source is lit and spectra are taken of a reference substrate without the films/structures of interest, and then a spectrum of the sample of interest. The sample spectra is normalized by the transparent substrate spectra, thus producing a sample transmission spectra that ranges from 0 to 100% transmission (as compared to the bare substrate). From these two measurements, the 0^{th} order absorbance (Aₒ) can be calculated as A₀=1−R₀−T₀.

### Example 7

### Experimental Results

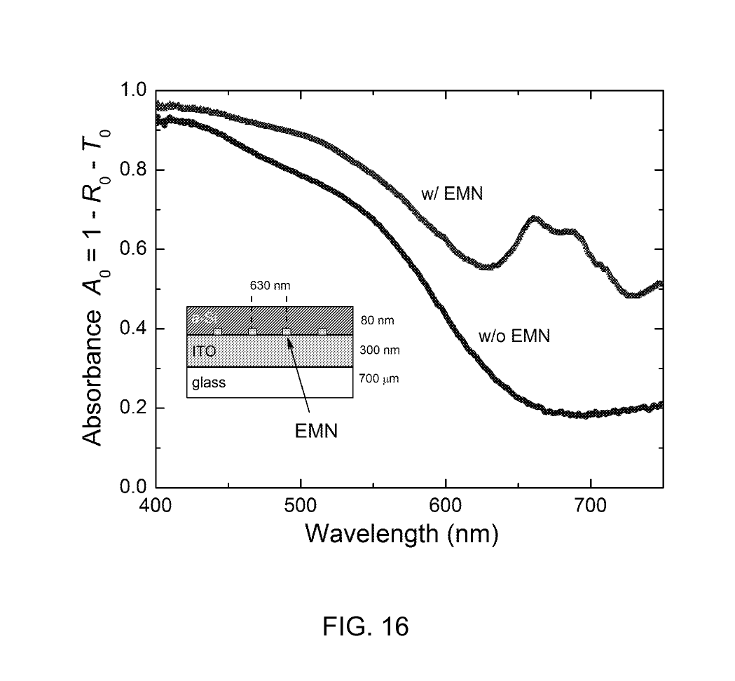

Based on measurements of the 0^{th} order transmission and reflection of an 80 nm thick a-Si film on ITO coated glass, FIG. 16 show experimental results for absorbance with and without the nanopattern shown in FIG. 14. There is general agreement with the aforementioned simulations showing that the EMN enhances the absorption, particularly at longer wavelengths.

At about 660 nm, for example, the absorption in the EMN sample is 3.5 times that of the sample without the EMN, while the total wavelength-integrated enhancement is by more than 50%.

### Example 8

### Triangle Nanopatterns (Nanoholes Array)

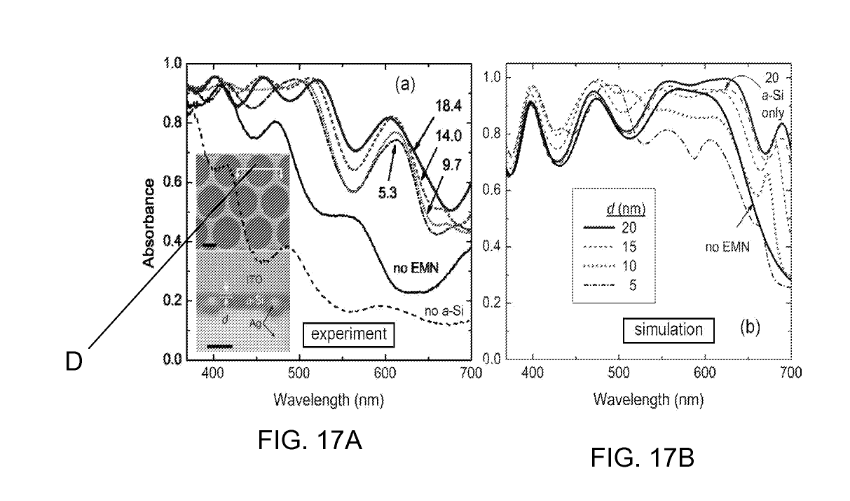

A series of nanohole arrays with different embed depths d were prepared. Thin layer of a-Si was deposited on an ITO-glass substrate by PECVD, and then transferred a polystyrene sphere array as a mask for Ag deposition, which was preceded by a reduction of the sphere diameters by reactive ion etching. Spheres having the diameter of about 500 nm were employed to form several square centimeters in area arrays with low defect density. The spheres were then etched to about 400 nm diameter. A 2nd a-Si deposition followed to embed the 50 nm-thick Ag pattern and form an embedded nanopattern. An SEM image of the Ag pattern on a-Si, before the 2nd a-Si deposition, is shown in the middle image in the upper inset to FIG. 17A. By focused ion beam milling, the nanopattern embedded in the a-Si was examined in cross-section, as shown in the lower inset, for a cut defined by line D in the upper inset. The two branches of the Ag pattern are clearly seen embedded in a-Si. By tuning the deposition time for the initial a-Si layer, Ag networks were generated with embedding depths d=5.3, 9.7, 14.0 and 18.4 nm, while keeping the total a-Si thickness constant at 80 nm. After final a-Si deposition, all samples were covered by a thick layer of Ag (>300 nm) as a back reflector.

Reflectance R of these samples was measured by an integrating sphere reflectometer. The total absorbance A is shown in FIG. 17A, obtained via A=1−R, since the transmittance of the samples is zero. Compared to the “no nanopattern” (no EMN) control, the absorbance of the nanopattern-integrated structures can be seen to exhibit an enhancement that increases with increasing embed depth. Since the absorbance is obtained using unpolarized light, and averaged over all incident angles, this broadband enhancement effect is more robust than some specific cavity or resonating mode enhancement effect. The large oscillating peaks seen in all curves are artifacts associated with the rather large thickness (500 nm) of the commercial ITO-coated glass, as is the large (˜30%) absorbance above 600 nm in the control samples.

Simulations of total absorbance are plotted in FIG. 17B. Employed parameters for the array pitch, hole diameter, and ITO, a-Si, and Ag thicknesses were identical to the experimental values, and d was varied from 5 nm to 20 nm. Like the square and cross nanopatterns, there is a notable increase in absorbance above the ‘no EMN’ case for this nanohole array nanopattern, in both experiment (+41% increase) and simulation (+10% increase), after integrating over the 350-700 nm wavelength range. Similar to the analysis for the cross pattern, PV values from these absorbance curves can be calculated, and an increase of a 61% (12%) is obtained in the calculated J_{sc} values over the controls for the experimental (simulated) data.

### Example 9

### Nanostructures Assembled from Insulated Nanoparticles

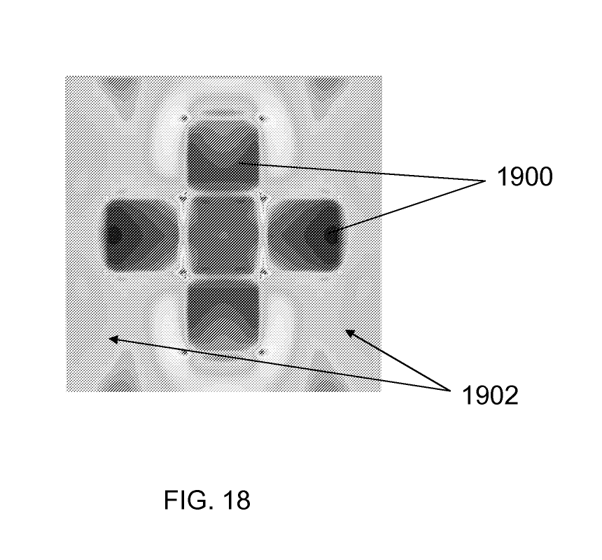

To test whether assembling a nanostructure (such as the cross) from an ensemble of smaller nanoparticles retains the desired light-matter interaction effect, leading to near-field scattering-enhanced optical absorption in the semiconductor around the nanostructure, the interaction of light with a cross structure composed of 5 200×200 nm² insulated Ag squares (20 nm thick), as shown in FIG. 18, was simulated. Each square fully encompassed in a thin insulating sheath. The power loss density (i.e. absorption) was simulated as a function of space, across a plane through the middle of the 5-square arrangement, at λ=500 nm. The absorption remained low in the metal regions 1900 compared to the a-Si regions 1902, mimicking the response of a unibody nanostructures, respectively. This result suggests that the assembling nanostructures from smaller particles will work—light is preferentially absorbed in the volume not only outside the metal, but outside the dielectric coating, and therefore in the a-Si as desired.

### Example 10

### Insulated Nanostructures

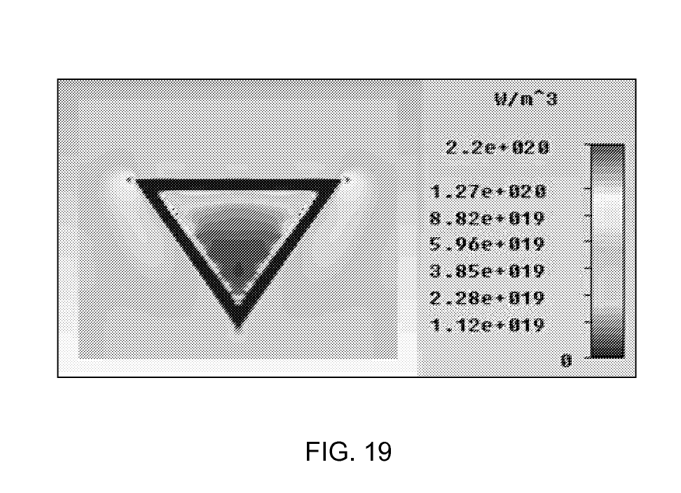

Array of insulted nanotriangles were embedded in a a-Si film. FIG. 19 illustrates a contour plot of power loss density at λ=450 nm for a 100 nm-side×40 nm thick Ag triangle with a 10 nm-thick insulating coating embedded in 80 nm-thick a-Si. The absorption remained low in the metal region of the nanotriangle compared to the a-Si regions outside the nanotriangle, mimicking the response of a unibody nanostructures, respectively. The resulting power loss density in the a-Si layer shows very strong absorption in the mid-visible, as well as long wavelength absorption well in excess of what can be expected to be achieved in such a thin a-Si film in the absence of an embedded nanopattern.

### Example 11

### Simulated Cross Embedded Nanopattern

The simulated cross EMN was comprised of an array of h_{EMN}=20 nm thick Ag crosses with 100 nm×300 nm segments in a 400×400 nm² unit cell, including four cells as shown in

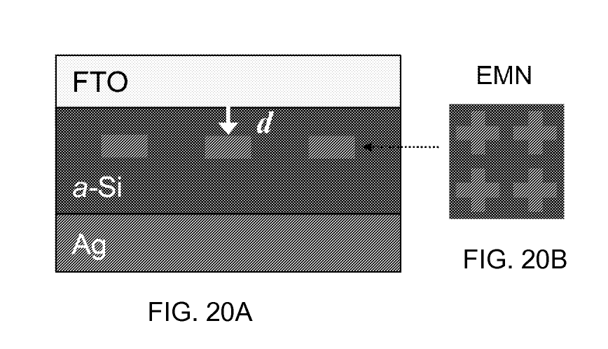

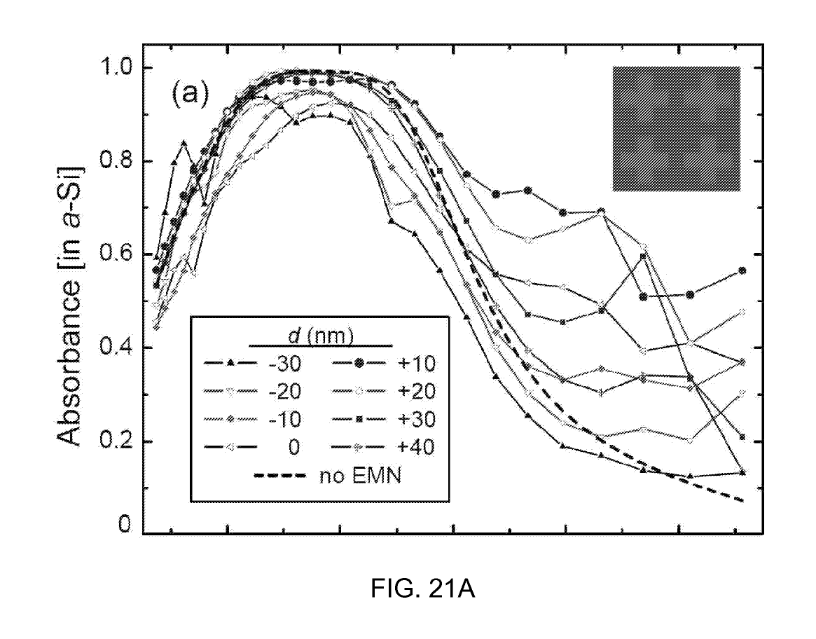

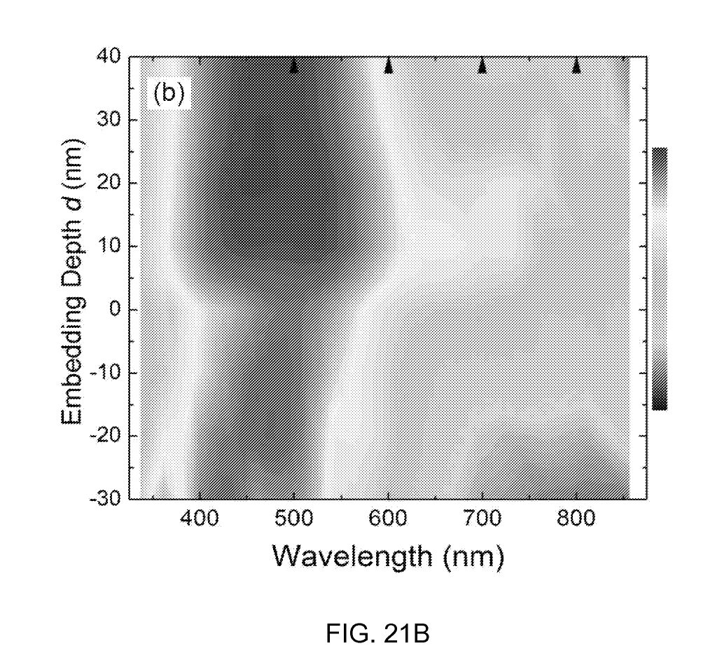

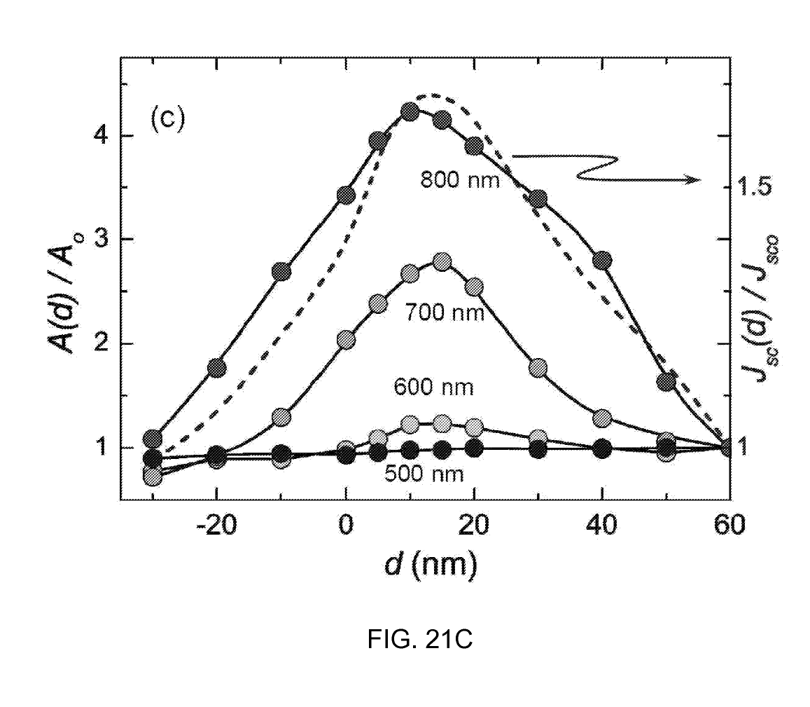

FIG. 20A and FIG. 20B, embedded at a depth D. 50 nm thick fluorine-doped tin oxide (FTO) and h_{Si}=60 nm thick silicon were utilized, and the EMN embedding depth d was varied from −30 to +60 nm (i.e. fully within the FTO to fully within the back Ag reflector). The simulations consisted of placing periodic boundary conditions on the unit cell in the plane of the EMN, and simulating the response to a normally-incident, linearly polarized plane wave, as shown in FIG. 21. The 0^{th} order reflectance R and transmittance T of the incident wave normal to the surface were simulated, yielding absorbance A=1−R (since T=0 for the totally reflective back contact). Simulations were performed using commercial, finite element analysis tools COMSOL Multiphysics and CTS Microwave Studio in the frequency-domain, with portions of the simulations cross-checked between the two software packages. Full dispersion relations from standard literature sources were employed for all materials in the simulations (D. T. Pierce, W. E. Spicer, Phys. Rev. B 1972, 5, 3017-3029 for Si; E. D. Palik, (ed.) Handbook of Optical Constants of Solids. Academic, New York, 1985; D. J. Nash, J. R. Sambles, J. Mod. Opt. 1996, 43, 81-91; and P. B. Johnson, R. W. Christy, Phys. Rev. B 1998, 6, 4370-4379 for Ag; and Asahi glass, www.agc.com for FTO.) Moreover, simulations were compared using optical constants for silver from literature (e.g. E. D. Palik, (ed.) Handbook of Optical Constants of Solids. Academic, New York, 1985; D. J. Nash, J. R. Sambles, J. Mod. Opt. 1996, 43, 81-91; and P. B. Johnson, R. W. Christy, Phys. Rev. B 1998, 6, 4370-4379.)

FIG. 21A shows the resulting simulated absorbance within the a-Si layer, obtained by integrating the calculated, time-averaged power loss density P̅_{L} over the a-Si volume, versus incident light wavelength, for different embedding depths d of the EMN placement between on-the-top (d≦−20 nm) and on-the-bottom (d≧+40) contacts. By varying d, all possible configurations for which nanopattern can be integrated into an absorber film are examined, with d≦−h_{EMN} representing top-patterning or above, −h_{EMN}<d≦0 partially embedded, 0<d<h_{Si}−h_{EMN} fully embedded, and d≧h_{Si}−h_{EMN} bottom-patterning (i.e. on or in the Ag back reflector), where h_{Si} is height/thickness of the silicon film and h_{EMN} is height/thickness of the nanopattern.

The dashed line shows the simulated absorbance without an integrated EMN. Here,

$${\overline{P}}_{L} = \frac{ω {ɛ}^{″}}{2} {\vert {E}^{ρ} \vert}^{2} + \frac{{ωμ}^{″}}{2} {\vert {H}^{ρ} \vert}^{2}$$

was derived from Poynting's theorem, with ω the light frequency, ∈″ and μ″ the imaginary parts of the relative complex dielectric constant and permeability of the absorber, and E and H the local electric and magnetic fields, respectively. Since μ″≈0 for a-Si, the magnetic term does not contribute to absorption. It can be seen from the figure that when the Ag cross pattern is present but positioned above the a-Si layer (d=˜30 nm, i.e. bottom surface of EMN lying 10 nm above the FTO/a-Si interface), the absorbance in a-Si is less than the bare a-Si, “no EMN” condition, across most of the 350 nm to 850 nm range investigated. This appears rational since Ag, which in the employed cross pattern covers 5/16˜38% of the exposed surface, is known to be highly reflective in this visible frequency range. As the Ag pattern is brought closer to and then embedded into the a-Si layer (as d is increased from −30 nm to 0 nm), however, an overall increase in absorbance is observed throughout the spectrum, but especially at long wavelengths (λ>600 nm). As the embedding depth is further increased, the total absorbance in a-Si does as well, until it reaches a maximum between d=10 nm and 20 nm. Finally, continued increases in d (e.g., +30 to +40 nm) ultimately suppressed absorbance, again especially so at long wavelengths. The absolute absorbance in the a-Si in the simulations in FIG. 2(a) reaches more than 80% for this optimum embed depth regime.

FIG. 21B presents a contour plot of a-Si absorbance versus wavelength for the simulations of FIG. 21A, with a 0-1 linear color scale on the right. From this plot, an optimum embedding depth near d=15 nm for which a somewhat broad, high absorption band develops can be discerned. Significant below-gap (i.e., above 2=hc/eE_{g}˜700 nm, where E_{g}˜1.7 eV is the nominal band gap of a-Si) absorption can be seen for EMN depths near the vertical middle of the structure, as opposed to those near the top FTO and bottom Ag surfaces. From these data in this structure, the depth dependence of the absorbance A(d) within the a-Si volume, for fixed wavelengths, can be extracted. For example, the free-space wavelengths λ=500, 600, 700 and 800 nm were selected for display, as indicated by arrows at the top of the contour plot.

Referring to FIG. 21C, normalized to the control, “no EMN” absorbance Aₒ, the resulting optical absorbance enhancement factor A(d)/Aₒ versus d were plotted. The scale on the left refers to absorbance enhancement at fixed wavelengths versus embed depth d, relative to an EMN-free control sample, showing strongest effects at long wavelengths (>300% at 800 nm). The scale on the right refers to variation in calculated short circuit current density with d, relative to the control, showing maximum ˜70% increase near d=15 nm.

As is seen in FIG. 21C, embedding a metal nanopattern inside an optical absorber can enhance, by significant amounts, the optical absorbance of the surrounding semiconductor medium. For the example structure utilized in this simulation, the enhancement is ˜175% at λ=700 nm (A/Aₒ>2.5), and ˜325% at λ=800 nm. According to FIG. 21C, for the instant simulation, an optimum embedding depth is in the range d=10 to 20 nm for the wavelength values depicted, but especially for the longer, near- and sub-gap wavelengths. In contrast, the conventional top (d=−20 nm) and bottom (d≧+40 nm) pattern placements yield far less enhancement at most wavelengths, as compared to the embedded situations.

The effect this EMN concept can have on a photovoltaic solar cell can be estimated, within the assumptions that p- and n-doped layers on either side of the undoped a-Si film do not appreciably change the optical absorbance, and that this absorbance can be equated with external quantum efficiency. Using for the short circuit current density J_{sc}=(e/hc)∫S(λ)A(λ)λdλ where e, h and c are the elementary charge, Planck's constant and the speed of light, respectively, and S(λ) is the power density spectrum for solar irradiation (AM1.5), J_{sc} can be calculated for each embedded depth d. Referring to FIG. 21C, the ratios of these J_{sc} values to that for the ‘no EMN’ control were plotted, calculated to be J_{sc}=12.4 mA/cm². Consistent with the simulated A(λ), J_{sc} is enhanced upon embedment, peaking near d=15 nm with a 70% increase over the control (J_{sc}>21 mA/cm²), a value 20% higher than the record number for single junction a-Si (See e.g. J. Meier, J. Spitznagel, U. Kroll, C. Bucher, S. Fay, T. Moriarty, A. Shah, Thin Solid Films 2004, 451-452, 518-524), achieved in more than 4 times thicker films. For a typical open circuit voltage of V_{oc}=0.88 V and fill factor of 0.7 for a-Si solar cells, this corresponds to a power conversion efficiency η of 13%, close to 30% higher than the state-of-the-art for single junction a-Si PV (See e.g. S. Benagli, D. Borrello, E. Vallat-Sauvain, J. Meier, U. Kroll, J. Hoetzel, J. Bailat, 24th Eur. Photovolt. Sol. Energy Conf. 2009, 3BO.9.3, 2293-2298).

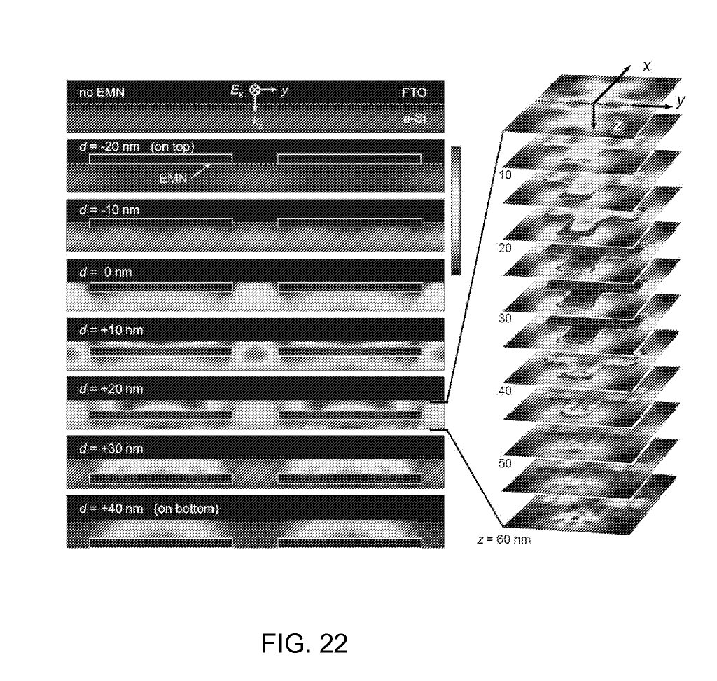

FIG. 22 presents simulated power loss density at 2=700 nm linearly polarized (Eₓ) incidence for the Ag cross EMN, viewed in y-z-plane cross-sections cut through the middle of two unit cells, for various embed depths d. The light-sample coordinate system is indicated, and only the FTO and a-Si layers are shown, with the EMN indicated by its outline. The 0-5×10⁻¹⁰ W/m³ linear color scale is shown. On the right is a series of x-y slices of the d=20 nm depth P̅_{L} at different z-positions, providing a separate perspective of the spatial distribution of electromagnetic absorption, which is primarily in the a-Si. Referring to FIG. 22, the top panel on the left set of images shows P̅_{L}(y,z)|ₓ for the situation without the Ag EMN (i.e. bare a-Si), as well as the orientations of light propagation k_{z} and electric field polarization Eₓ. Successive panels below this correspond to y-z-plane cross-sections of P̅_{L} at depths between d=−20 and +40 nm, in 10 nm steps, for a cut (i.e. fixed x) through the middle of the crosses in the EMN array. All panels contain the same linear color scale shown, varying from 0 to 5×10⁻¹⁰ W/m³, which corresponds to an optical density equivalent to ˜1 sun (1 kW/m²). These images serve to implicate the mechanism responsible for the optical absorbance enhancement: near-field scattering-enhanced concentrations of P̅_{L} within the a-Si in the vicinity of the embedded nano-crosses, strongest in intensity above and between crosses for the d=10 and 20 nm EMN depths. Upon embedment, the scattered electric field concentrates in the a-Si, which has a much higher absorption coefficient than FTO or bulk Ag at optical frequencies. FIG. 22 also illustrates that there is a low absorption by the nanopattern itself (see e.g., the z=30 mm slice through the midplane of the nanopattern). It can be seen that P̅_{L}(x, y, z) reaches maximal values between d=10 and 20 nm, between and above individual crosses, respectively.

Electromagnetic simulations show that a metamedium comprised of a subwavelength-sized metal nanopattern embedded in an optical absorber exhibits a spatially inhomogeneous electromagnetic response, with incident light intensely scattered, and to an extent focused, into localized regions within the absorber. This organized near-field scattering effect leads to strongly enhanced absorbance in these regions and, accounting for the whole sample volume, significant increases in short circuit current (+70%) and photovoltaic performance (+30%) over that of a control. The enhancement is particularly strong in the near infrared, more than 4 times that in the control at 2=800 nm.

### Example 12

### Comparison of Metallic and Non-Metallic Embedded Nanopattern

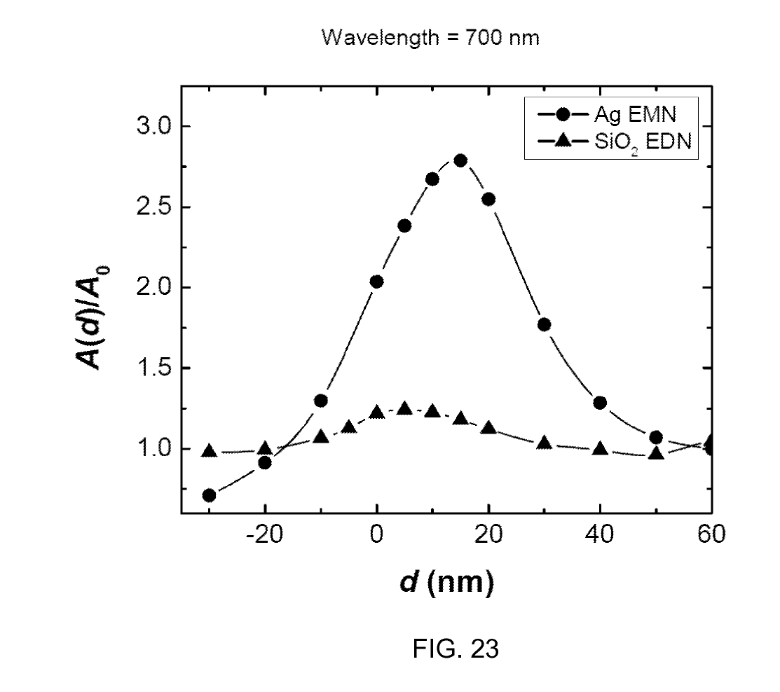

FIG. 23 illustrates results of two simulations for identical thickness silicon layer (60 nm) embedded with identical thickness (20 nm) and shape (100×300 nm crosses, as in Example 11) on 400 nm pitches, both for 700 nm light. The first simulation is the standard embedded metallic nanopattern (EMN), and the second simulation utilized an embedded dielectric nanopattern (EDM), comprised of silicon oxide, SiO₂. As can be seen from FIG. 23, while the EMN outperformed the EDM, embedding dialectric nanopattern according to the present disclosure also had a beneficial effect on light absorbance by the silicon layer.

In some embodiments, a light absorbing layer for use in a photovoltaic junction includes a light absorbing material with a metallic nanopattern embedded within the light absorbing material, wherein the nanopattern comprises a planar array of nanostructures. In some embodiments, the nanostructures, are coated with electrically insulating coating.

In some embodiments, a photovoltaic junction includes a light absorbing layer of a light absorbing material having a metallic nanopattern embedded therein, wherein the nanopattern comprises a planar array of nanostructures.

In some embodiments, a solar cell includes a substrate, a photovoltaic junction formed on the substrate and comprising a light absorbing layer of a light absorbing material having a metallic nanopattern embedded therein, wherein the nanopattern comprises a planar array of nanostructures, a back electrode disposed between the substrate and the photovoltaic junction, and a front electrode disposed on a front surface of the photovoltaic junction.

In some embodiments, a light absorbing device comprises a light absorbing material having a front surface and a back surface, and a planar array of metallic nanostructures embedded within the light absorbing material between the front surface and the back surface of the light absorbing material. In some embodiments, the nanostructures are metallic.

In some embodiments, a photovoltaic cell comprises a photovoltaic junction having a light absorbing layer; a planar array of metallic nanostructures embedded within the light-absorbing layer; and a front electrode and a rear electrode electrically connected to the photovoltaic junction to collect electrical current generated in the photovoltaic junction.

In some embodiments, a method for forming a light absorbing device comprises providing a first thickness of a first photovoltaic material; disposing a planar array of metallic nanostructures on a surface of the first photovoltaic material; and adding a second thickness of the first photovoltaic material over the metal layer.

In some embodiments, a method for increasing light absorption in a light absorbing material, the method comprises providing a light absorbing material having a light absorbing surface and a back surface opposite the light absorbing surface; and embedding a planar nanopattern of nanostructures into the light absorbing material between the light absorbing surface and the back surface, wherein, upon exposure of the light absorbing material, absorption of light by the light absorbing material is increased.

All patents, patent applications, and published references cited herein are hereby incorporated by reference in their entirety. While the devices and methods of the present disclosure have been described in connection with the specific embodiments thereof, it will be understood that they are capable of further modification. Furthermore, this application is intended to cover any variations, uses, or adaptations of the devices and methods of the present disclosure, including such departures from the present disclosure as come within known or customary practice in the art to which the devices and methods of the present disclosure pertain.

What is claimed is:

1. A light absorbing device comprising:
a light absorbing material having a front surface and a back surface;
a planar array of nanostructures embedded within the light absorbing material between the front surface and the back surface of the light absorbing material.

2. The light absorbing device of claim 1 wherein the nanostructures are metallic.

3. The light absorbing device of claim 1 wherein the light absorbing material is a photovoltaic material.

4. The light absorbing device of claim 3 wherein the light absorbing material is combined with one or more other photovoltaic materials to form a photovoltaic junction.

5. The light absorbing device of claim 3 wherein the light absorbing material forms an i-region of a p-i-n photovoltaic junction.

6. The light absorbing device of claim 1 wherein the planar array of nanostructures is positioned between about 5 nm and about 20 nm from the front surface of the light absorbing material.

7. The light absorbing device of claim 1 wherein the planar array of nanostructures has a pitch between about 50 nm and 800 nm.

8. The light absorbing device of claim 1 wherein the nanostructures of the planar array of nanostructures have dimensions between about 20 nm and about 800 nm.

9. The light absorbing device of claim 1 wherein the nanostructures of the planar array of nanostructures are insulated with an insulating coating.

10. The light absorbing device of claim 9 wherein the insulating coating around the nanostructures is sized so that an electric field generated by incident light scattered from the nanostructures extends outside the coating.

11. The light absorbing device of claim 1 wherein the nanostructures of the planar array of nanostructures comprise a plurality of nanoparticles.

12. The light absorbing device of claim 11 wherein the nanoparticles are insulated.

13. A photovoltaic cell comprising:
a photovoltaic junction having a light absorbing layer;
a planar array of metallic nanostructures embedded within the light-absorbing layer; and
a front electrode and a rear electrode electrically connected to the photovoltaic junction to collect electrical current generated in the photovoltaic junction.

14. The photovoltaic cell of claim 13 wherein the planar array of nanostructures has a pitch between about 50 nm and 800 nm.

15. The photovoltaic cell of claim 13 wherein the nanostructures of the planar array of nanostructures have dimensions between about 20 nm and about 800 nm.

16. A method for forming a light absorbing device comprising:
providing a first thickness of a first photovoltaic material;
disposing a planar array of metallic nanostructures on a surface of the first photovoltaic material; and
adding a second thickness of the first photovoltaic material over the metal layer.

17. The method of claim 16 wherein the step of disposing comprises:
forming a planar array of nanostructures from a plurality of nanoparticles; and
transferring the planar array onto a surface of the first photovoltaic material.

18. The method of claim 16 wherein the step of disposing comprises:
forming an array of nanoparticles on the surface of the first photovoltaic layer;
depositing a metal layer onto the first photovoltaic material; and
removing the nanoparticles from the first photovoltaic material.

19. The method of claim 18 wherein the nanoparticles are insulated.

20. The method of claim 16 further comprising:
disposing the first photovoltaic material over a second photovoltaic material; and
disposing a third photovoltaic material over the first photovoltaic material, wherein the first photovoltaic material forms an intrinsic region of a p-i-n photovoltaic junction, and the second photovoltaic material and the third photovoltaic materials form oppositively charged doped regions of the p-i-n photovoltaic junction.

21. The method of claim 16 wherein the second thickness of the first photovoltaic material is between about 5 nm and about 20 nm.

22. A method for increasing light absorption in a light absorbing material, the method comprising:
providing a light absorbing material having a light absorbing surface and a back surface opposite the light absorbing surface; and
embedding a planar nanopattern of metallic nanostructures into the light absorbing material between the light absorbing surface and the back surface,
wherein, upon exposure of the light absorbing material, absorption of light by the light absorbing material is increased.
